(19) United States
(12) Patent Application Publication
(10) Pub. No.: US 2025/0201789 A1
(43) Pub. Date: Jun. 19, 2025

(54) ELECTRONIC DEVICE

(71) Applicant: InnoLux Corporation, Miao-Li County (TW)

(72) Inventors: Hsu-Kuan HSU, Miao-Li County (TW); Tzu-Chieh LAI, Miao-Li County (TW); Chih-Chin KUO, Miao-Li County (TW); En-Hsiang CHEN, Miao-Li County (TW); WenQi LIN, Miao-Li County (TW); Mao-Shiang LIN, Miao-Li County (TW)

(21) Appl. No.: 18/953,783

(22) Filed: Nov. 20, 2024

(30) Foreign Application Priority Data
Dec. 18, 2023 (CN) 202311736591.4

(51) Int. Cl. H01L 25/16; H01L 31/0216; H01L 33/60; H10K 30/50

(52) U.S. Cl. CPC H01L 25/167; H10F 77/311; H10H 20/856; H10K 30/50

(57) ABSTRACT

An electronic device comprises: a first panel comprising: a first display layer having a first side and a second side opposite thereto, wherein the first display layer receives an incident light and reflects a first reflected light, a light in the incident light other than the first reflected light is a first transmitting light, the first side is a light emitting side of the first reflected light, and the second side is a transmitting side of the first transmitting light; a first photoelectric conversion unit disposed adjacent to the second side, wherein the first photoelectric conversion unit absorbs the first transmitting light and converts it into electrical energy; and a second panel disposed opposite to the first panel, wherein the second panel comprises a second display layer, and the first photoelectric conversion unit is disposed between the first display layer and the second display layer.

### CROSS-REFERENCE TO RELATED APPLICATIONS

This application claims the benefits of the Chinese Patent Application Serial Number 202311736591.4, filed on Dec. 18, 2023, the subject matter of which is incorporated herein by reference.

### BACKGROUND

### Field

The present disclosure provides an electronic device and, more specifically an electronic device comprising a photoelectric conversion unit.

### Description of Related Art

As science and technology advance day by day, display technology continues to improve. In order to meet consumers' requirements for display quality of display devices, manufacturers are committed to improving display devices.

However, today's display devices still have some parts that need to be improved. For example, how to effectively achieve energy saving requires continuous research and development of improved electronic devices.

### SUMMARY

The present disclosure provides an electronic device, which comprises: a first panel, comprising: a first display layer having a first side and a second side opposite to each other, wherein the first display layer receives an incident light and reflects a first reflected light, light in the incident light other than the first reflected light is a first transmitting light, the first side is a light emitting side for the first reflected light, and the second side is a transmitting side for the first transmitting light; a first photoelectric conversion unit disposed adjacent to the second side, wherein the first photoelectric conversion unit absorbs at least part of the first transmitting light and converts it into electrical energy; and a second panel disposed opposite to the first panel, wherein the second panel comprises a second display layer, and the first photoelectric conversion unit is disposed between the first display layer and the second display layer.

The present disclosure also provides another electronic device, which comprises: a panel, comprising: a first pixel unit and a second pixel unit respectively having a first side, wherein the first pixel unit and the second pixel unit respectively emit different display lights and emit from the first sides of the first pixel unit and the second pixel unit respectively; a first photoelectric conversion unit adjacent to the first side of the first pixel unit; and a second photoelectric conversion unit adjacent to the first side of the second pixel unit, wherein the first photoelectric conversion unit absorbs at least part of the display light emitted by the first pixel unit and converts it into electrical energy, and the second photoelectric conversion unit absorbs at least part of the display light emitted by the second pixel unit and converts it into electrical energy, wherein a wavelength range of light absorbed by the first photoelectric conversion unit is different from a wavelength range of light absorbs by the second photoelectric conversion unit.

Other novel features of the disclosure will become more apparent from the following detailed description when taken in conjunction with the accompanying drawings.

### BRIEF DESCRIPTION OF DRAWINGS

FIG. 1 is a schematic diagram of an electronic device according to one embodiment of the present disclosure.

FIG. 2 is a schematic diagram showing light absorption and reflection of an electronic device according to one embodiment of the present disclosure.

FIG. 3A and FIG. 3B respectively are schematic diagrams showing the photoelectric conversion units according to one embodiment of the present disclosure.

FIG. 4 is a schematic diagram of an electronic device according to one embodiment of the present disclosure.

FIG. 5 is a schematic diagram of an electronic device according to one embodiment of the present disclosure.

FIG. 6 is a schematic diagram of an electronic device according to one embodiment of the present disclosure.

FIG. 7 is a schematic diagram of an electronic device according to one embodiment of the present disclosure.

FIG. 8 is a schematic diagram of an electronic device according to one embodiment of the present disclosure.

FIG. 9 is a schematic diagram of an electronic device according to one embodiment of the present disclosure.

FIG. 10A to FIG. 10C respectively are enlarge views of a part of an electronic device according to one embodiment of the present disclosure.

### DETAILED DESCRIPTION

The following is a detailed description of the electronic device according to the embodiment of the present disclosure. It should be understood that the following description provides many different embodiments for implementing different aspects of some embodiments of the present disclosure. The specific components and arrangements described below are only used to briefly and clearly describe some embodiments of the present disclosure. Of course, these are only examples and not limitations of the present disclosure. In addition, similar and/or corresponding reference numerals may be used to identify similar and/or corresponding elements in different embodiments to clearly describe the present disclosure. However, the use of these similar and/or corresponding reference numerals is only for the purpose of simply and clearly describing some embodiments of the present disclosure, and does not represent any correlation between the different embodiments and/or structures discussed.

It should be understood that relative terms, such as “lower” or “bottom” or “higher” or “top” may be used in the embodiments to describe the relative relationship of one element to another element shown in the figures. It should be understood that if the device in the figures is turned upside down, elements described as being on the “lower” side would then be elements described as being on the “higher” side. The embodiments of the present disclosure can be understood together with the drawings, and the drawings of the present disclosure are also regarded as part of the disclosure description. It should be understood that the drawings of the present disclosure are not drawn to scale and, in fact, the dimensions of elements may be arbitrarily enlarged or reduced in order to clearly illustrate features of the present disclosure.

One structure (or a layer, a component, or a substrate) described in the present disclosure is disposed on/above another structure (or a layer, a component, or a substrate), which may mean that the two structures are adjacent and directly connected, or may mean that two structures are adjacent rather than directly connected. Indirect connection means that there is at least one intermediary structure (or an intermediary layer, an intermediary component, an intermediary base material, an intermediary spacer) between two structures, the lower surface of one structure is adjacent to or directly connected to the upper surface of the intermediary structure, and the upper surface of another structure is adjacent to or directly connected to the lower surface of the intermediary structure. The intermediary structure may be composed of a single-layer or multi-layer physical structure or a non-physical structure, and is not limited. In the present disclosure, when a certain structure is disposed “on” other structures, it may mean that a certain structure is “directly” on other structures, or that a certain structure is “indirectly” on other structures, that is, there is at least one structure sandwiched between a certain structure and other structures.

Furthermore, it should be understood that the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation. The same terms may not be used in the claims and the description. For example, a first element in the description may be a second element in the claims.

In some embodiments of the present disclosure, terms related to joining or connecting, such as “connection”, “interconnection”, etc., unless otherwise defined, may mean that two structures are in direct contact, or may also mean that the two structures are not in direct contact where other structures are located between the two structures. The terms “joint” or “connection” can also include situations where both structures are movable, or where both structures are fixed. In addition, the terms “electrical connection” or “coupling” include any direct and indirect means of electrical connection.

In the present specification, the terms, such as “about”, “substantially”, or “approximately”, are generally interpreted as within 10%, 5%, 3%, 2%, 1%, or 0.5% of a given value or range. Unless otherwise stated, when a value is “in a range from a first value to a second value” or “in a range between a first value and a second value”, the value can be the first value, the second value, or another value between the first value and the second value. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°. In the present disclosure, the terms “a given range is a first value to a second value” and “a given range falls within the range of a first value to a second value” mean that the given range includes the first value, the second value, or another value between the first value and the second value.

Furthermore, according to embodiments of the present disclosure, an optical microscopy (OM), a scanning electron microscope (SEM), a film thickness profiler (α-step), an ellipse thickness gauge or other suitable manners may be used to measure the thickness, length, width of each component or the distance and angle between components. Specifically, according to some embodiments, a scanning electron microscope can be used to obtain cross-sectional images of the structure and measure the thickness, length, width of each component, or the distance and angle between components.

Throughout the disclosure and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

It should be understood that the following embodiments can be replaced, reorganized, and combined with features of several different embodiments without departing from the spirit of the present disclosure to complete other embodiments. As long as the features of the various embodiments do not violate or conflict the spirit of the present disclosure, they can be used in any combination.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way. The present disclosure can be understood by referring to the following detailed description in conjunction with the accompanying drawings. It should be noted that, in order to facilitate readers' understanding and for the simplicity of the drawings, many of the drawings in the present disclosure only depict a part of the electronic device, and specific components in the drawings are not drawn according to actual scale. In addition, the number and size of each component in the figures are only for illustration and are not used to limit the scope of the present disclosure.

Throughout the disclosure and the appended claims of the present disclosure, certain words are used to refer to specific elements. Those skilled in the art should understand that electronic device manufacturers may refer to the same components by different names. The present specification does not intend to distinguish between elements that have the same function but have different names.

The electronic device of the present disclosure may include electronic components. Electronic components may include passive components, active components, or a combination thereof, for example, capacitors, resistors, inductors, varactor diodes, variable capacitors, filters, diodes, transistors, sensors, microelectromechanical system (MEMS) components, liquid crystal chips, but the present disclosure is not limited thereto. Diodes may include light-emitting diodes or non-light-emitting diodes. Diodes include P-N junction diodes, PIN diodes or constant current diodes. The light emitting diodes may include, for example, organic light emitting diodes (OLEDs), mini LEDs, micro LEDs, quantum dot LEDs, fluorescence, phosphors, other suitable materials, or a combination thereof, but the present disclosure is not limited thereto. Sensors may include, for example, capacitive sensors, optical sensors, electromagnetic sensors, fingerprint sensors (FPSs), touch sensors, antenna, or pen sensors, but the present disclosure is not limited thereto. In the following, a display device will be used as an electronic device to illustrate the present disclosure, but the present disclosure is not limited thereto.

The electronic device may include an imaging device, a laminating device, a display device, a backlight device, an antenna device, a tiled device, a touch electronic device (a touch display), a curved electronic device (a curved display) or a non-rectangular electronic device (a free shape display), but the present disclosure is not limited thereto. The electronic device may include, for example, liquid crystals, light emitting diodes, fluorescence, phosphors, other suitable display media, or a combination thereof, but the present disclosure is not limited thereto. The display device may be a non-self-luminous display device or a self-luminous display device; the antenna device may be a liquid crystal type antenna device or a non-liquid crystal type antenna device; and the sensing device may be a sensing device that senses capacitance, light, heat or ultrasonic waves; but the present disclosure is not limited thereto. The tiled device may be, for example, a tiled display device or a tiled antenna device, but the present disclosure is not limited thereto. It should be noted that the electronic device can be any combination of the above, but the present disclosure is not limited thereto. The electronic device may be a bendable or flexible electronic device. It should be noted that the electronic device may be any combination of the above, but the present disclosure is not limited thereto. In addition, the shape of the electronic device may be a rectangle, a circle, a polygon, a shape with curved edges, or other suitable shapes. Electronic devices may have peripheral systems such as drive systems, control systems, light source systems, shelf systems, etc. to support display devices, antenna devices, or tiled devices. It should be noted that in the following embodiments, features of several different embodiments can be replaced, reorganized, and mixed to complete other embodiments without departing from the spirit of the present disclosure. Features in various embodiments may be mixed and matched as long as they do not violate or conflict the spirit of the present disclosure with each other. It should be noted that the technical solutions provided in different embodiments below can be replaced, combined or mixed with each other to constitute another embodiment without violating the spirit of the present disclosure.

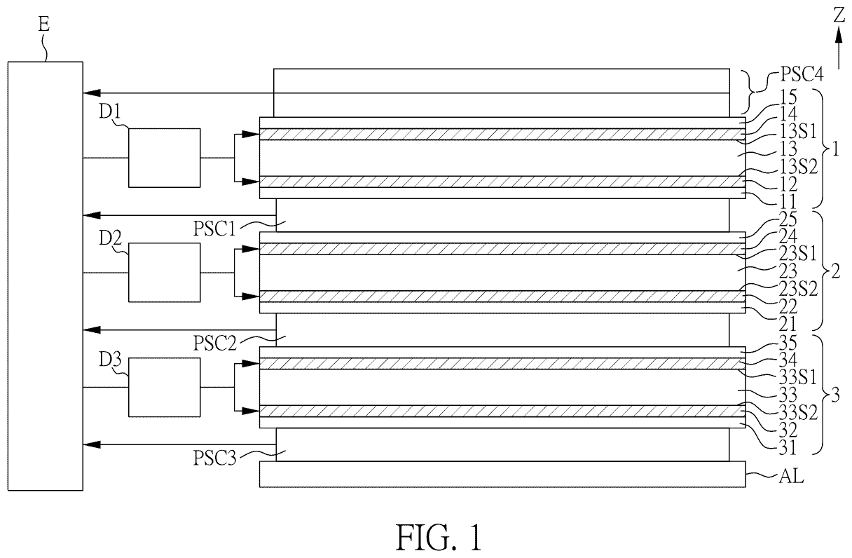

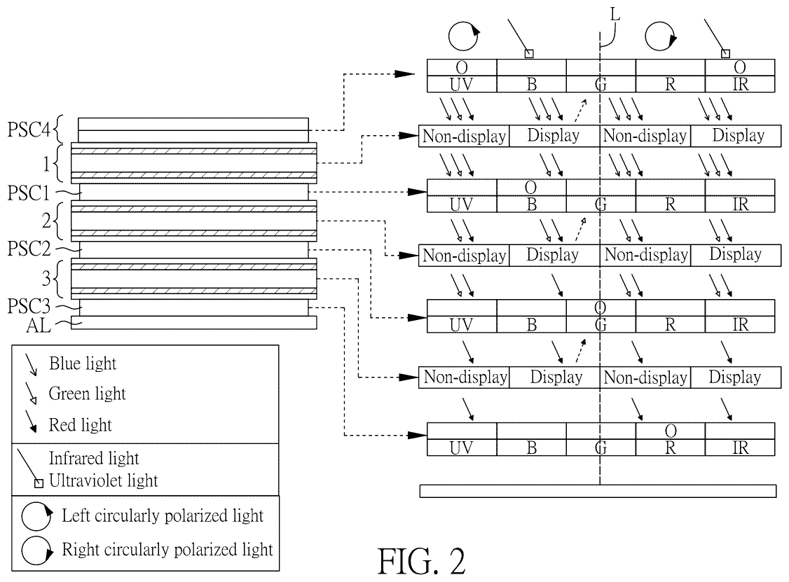

FIG. 1 is a schematic diagram of an electronic device according to one embodiment of the present disclosure. FIG. 2 is a schematic diagram showing light absorption and reflection of an electronic device according to one embodiment of the present disclosure. The electronic device shown in FIG. 2 is the same as that shown in FIG. 1. For convenience of explanation, some components of the electronic device in FIG. 2 are omitted.

In one embodiment of the present disclosure, as shown in FIG. 1 and FIG. 2, the electronic device may comprise: a first panel 1; a second panel 2 disposed opposite to the first panel 1; and a first photoelectric conversion unit PSC1. The first panel 1 may comprise: a first display layer 13 having a first side 13S1 and a second side 13S2 opposite to each other, wherein the first display layer 13 may receive an incident light and reflects a first reflected light, light in the incident light other than the first reflected light is a first transmitting light, the first side 13S1 is a light emitting side for the first reflected light, the second side 13S2 is a transmitting side for the first transmitting light. The first photoelectric conversion unit PSC1 is disposed adjacent to the second side 13S2, wherein the first photoelectric conversion unit PSC1 may absorb at least part of the first transmitting light and converts it into electrical energy. The second panel 2 may comprise a second display layer 23, the first photoelectric conversion unit PSC1 is disposed between the first display layer 13 and the second display layer 23. By arranging a photoelectric conversion unit in the electronic device, it can absorb at least part of the light in the incident light that is not reflected by the display layer and convert it into electrical energy for use by the electronic device, thereby saving power or improving the color purity of the reflected light.

In the present disclosure, the second display layer 23 have a third side 23S1 and a fourth side 23S2 opposite to each other, wherein the second display layer 23 may receive the first transmitting light that is not absorbed by the first photoelectric conversion unit PSC1 and reflects the second reflected light, and a wavelength of the first reflected light is different from a wavelength of the second reflected light. In addition, the light in the incident light other than the first reflected light, the light absorbed by the first photoelectric conversion unit PSC1 and the second reflected light may be, for example, a second transmitting light. Similarly, the third side 23S1 is the light emitting side for the second reflected light, and the fourth side 23S2 is the transmitting side for the second transmitting light.

In one embodiment of the present disclosure, as shown in FIG. 1 and FIG. 2, the electronic device may further comprise a second photoelectric conversion unit PSC2 disposed adjacent to the fourth side 23S2, and the second photoelectric conversion unit PSC2 may absorb at least part of the second transmitting light and convert it into electrical energy. In the present disclosure, the light absorbed by the first photoelectric conversion unit PSC1 is different from the light absorbed by the second photoelectric conversion unit PSC2, and for example, the wavelength ranges of light absorbed by the first photoelectric conversion unit PSC1 and the second photoelectric conversion unit PSC2 are different.

In one embodiment of the present disclosure, as shown in FIG. 1 and FIG. 2, the electronic device may further comprise a third panel 3; and a third photoelectric conversion unit PSC3, wherein the second panel 2 is disposed between the first panel 1 and the third panel 3. The third panel 3 comprises: a third display layer 33 having a fifth side 33S1 and a sixth side 33S2 opposite to each other, wherein the third display layer 33 may absorb the second transmitting light that is not absorbed by the second photoelectric conversion unit PSC2 and reflects a third reflected light, and the light in the incident light other than the first reflected light, the light absorbed by the first photoelectric conversion unit PSC1, the second reflected light, the light absorbed by the second photoelectric conversion unit PSC2 and the third reflected light is, for example a third transmitting light. Similarly, the fifth side 33S1 is the light emitting side for the third reflected light, and the sixth side 33S2 is the transmitting side for the third transmitting light. The third photoelectric conversion unit PSC3 is disposed adjacent to the sixth side 33S2, and the third photoelectric conversion unit PSC3 may absorb at least part of the third transmitting light and convert it into electrical energy. In the present disclosure, the wavelength of the third reflected light may be different from the wave length of the first reflected light and the wavelength of the second reflected light, the light absorbed by the third photoelectric conversion unit PSC3 may be different from the light absorbed by the first photoelectric conversion unit PSC1 and the light absorbed by the second photoelectric conversion unit PSC2. In other words, the third photoelectric conversion unit PSC3, the first photoelectric conversion unit PSC1 and the second photoelectric conversion unit PSC2 may be, for example, used to absorb light with different wavelengths and convert the absorbed light into electrical energy. By arranging multiple photoelectric conversion units mentioned above, the effect of photoelectric conversion can be improved, thereby saving power or improving the color purity of reflected light.

In the present disclosure, the first photoelectric conversion unit PSC1, the second photoelectric conversion unit PSC2 and the third photoelectric conversion unit PSC3 may be, for example, solar cells, and the types thereof may be the same or different. The first photoelectric conversion unit PSC1, the second photoelectric conversion unit PSC2 and the third photoelectric conversion unit PSC3 may respectively comprise a perovskite solar cell, a dye-sensitized solar cell or a combination thereof; but the present disclosure is not limited thereto. Perovskite solar cells can have the advantages of adjustable absorption wavelength, good light transmittance, and/or high photoelectric conversion efficiency. When the first photoelectric conversion unit PSC1, the second photoelectric conversion unit PSC2 and the third photoelectric conversion unit PSC3 respectively comprise the perovskite solar cells, the photoelectric conversion effect of the electronic device can be improved and the power saving can be achieved. In one embodiment of the present disclosure, the first photoelectric conversion unit PSC1 may be used to absorb the light with blue light wavelengths, ultraviolet light wavelengths and/or infrared light wavelengths, and convert the absorbed light into electrical energy. In one embodiment, the second photoelectric conversion unit PSC2 may be used to absorb light with green light wavelengths, blue light wavelengths, ultraviolet light wavelengths and/or infrared light wavelengths, and convert the absorbed light into electrical energy. The third photoelectric conversion unit PSC3 may be used to absorb light with red light wavelengths, green light wavelengths, blue light wavelengths, ultraviolet light wavelengths and/or infrared light wavelengths; but the present disclosure is not limited thereto.

In the present disclosure, the first display layer 13, the second display layer 23 and the third display layer 33 may be the same or different. The first display layer 13, the second display layer 23 and the third display layer 33 may respectively comprise cholesteric texture liquid crystals, polymer-stabilized cholesteric texture liquid crystals (PSCT LCs), suspended particle materials (SPD) or a combination thereof; but the present disclosure is not limited thereto. In one embodiment of the present disclosure, the first display layer 13, the second display layer 23 and the third display layer 33 may respectively comprise cholesteric texture liquid crystals. For example, the first display layer 13 comprises cholesteric texture liquid crystals that reflect blue light, the second display layer 23 comprises cholesteric texture liquid crystals that reflect green light, and the third display layer 33 comprises cholesteric texture liquid crystals that reflect red light; but the present disclosure is not limited thereto. The above display layers can reflect different colors of light according to the design. When the first display layer 13, the second display layer 23 and the third display layer 33 comply with the above design, the reflection efficiency of incident light can be improved, thereby improving the display quality of the electronic device. The first photoelectric conversion unit PSC1 may be used, for example, to absorb the light with wavelengths similar to the light reflected by the first display layer 13; the second photoelectric conversion unit PSC2 may be used, for example, to absorb the light with wavelengths similar to the light reflected by the second display layer 23; and the third photoelectric conversion unit PSC3 may be used, for example, to absorb the light with wavelengths similar to the light reflected by the third display layer 33; but the present disclosure is not limited thereto. In other embodiments, the first panel 1, the second panel 2 and/or the third panel 3 may comprise other reflective panel.

In the present disclosure, as shown in FIG. 1 and FIG. 2, the first panel 1 may comprise: a first substrate 11; a second substrate 15 disposed opposite to the first substrate 11; a first display layer 13 disposed between the first substrate 11 and the second substrate 15; a first electrode layer 12 disposed between the first substrate 11 and the first display layer 13; and a second electrode layer 14 disposed between the second substrate 15 and the first display layer 13, wherein the first display layer 13 is disposed between the first electrode layer 12 and the second electrode layer 14. The first display layer 13 may be controlled by applying voltage to the first electrode layer 12 and the second electrode layer 14, so that the electronic device displays an image. Similarly, the second panel 2 may comprise: a third substrate 21; a fourth substrate 25 disposed opposite to the third substrate 21, wherein the fourth substrate 25 is adjacent to the first substrate 11; a second display layer 23 disposed between the third substrate 21 and the fourth substrate 25; a third electrode layer 22 disposed between the third substrate 21 and the second display layer 23; and a fourth electrode layer 24 disposed between the fourth substrate 25 and the second display layer 23, wherein the second display layer 23 is disposed between the third electrode layer 22 and the fourth electrode layer 24. The second display layer 23 may be controlled by applying voltage to the third electrode layer 22 and the fourth electrode layer 24, so that the electronic device displays an image. Similarly, the third panel 3 may comprise: a fifth substrate 31; a sixth substrate 35 disposed opposite to the fifth substrate 31, wherein the sixth substrate 35 is adjacent to the third substrate 21; a third display layer 33 disposed between the fifth substrate 31 and the sixth substrate 35; a fifth electrode layer 32 disposed between the fifth substrate 31 and the third display layer 33; and a sixth electrode layer 34 disposed between the sixth substrate 35 and the third display layer 33, wherein the third display layer 33 is disposed between the fifth electrode layer 32 and the sixth electrode layer 34. The third display layer 33 may be controlled by applying violate to the fifth electrode layer 32 and the sixth electrode layer 34, so that the electronic device displays an image.

In the present disclosure, the first substrate 11, the second substrate 15, the third substrate 21, the fourth substrate 25, the fifth substrate 31 and the sixth substrate 35 may respectively comprise a rigid substrate or a flexible substrate. The materials of the first substrate 11, the second substrate 15, the third substrate 21, the fourth substrate 25, the fifth substrate 31 and the sixth substrate 35 may be the same or different. The material of the first substrate 11, the second substrate 15, the third substrate 21, the fourth substrate 25, the fifth substrate 31 and the sixth substrate 35 may respectively comprise glass, quartz, sapphire, ceramic, plastic, polycarbonate (PC), polyimide (PI), polypropylene (PP), polyethylene terephthalate (PET), polymethylmethacrylate (PMMA), other suitable materials or a combination thereof; but the present disclosure is not limited thereto. When the first substrate 11, the second substrate 15, the third substrate 21, the fourth substrate 25, the fifth substrate 31 and the sixth substrate 35 are flexible substrates, the electronic device of the present disclosure may be a flexible display device.

In the present disclosure, the materials of the the first electrode layer 12, the second electrode layer 14, the third electrode layer 22, the fourth electrode layer 24, the fifth electrode layer 32 and the sixth electrode layer 34 may be the same or different. The materials of the first electrode layer 12, the second electrode layer 14, the third electrode layer 22, the fourth electrode layer 24, the fifth electrode layer 32 and the sixth electrode layer 34 may respectively comprise a transparent conductive material, for example, indium zinc oxide (IZO), indium tin oxide (ITO), indium tin zinc oxide (ITZO), indium gallium zinc oxide (IGZO), aluminum zinc oxide (AZO) or a combination thereof; but the present disclosure is not limited thereto.

In one embodiment of the present disclosure, even not shown in the figure, the first panel 1 may comprise plural pixel regions (not shown in the figure), and the first photoelectric conversion unit PSC1 and the pixel regions of the first panel 1 may be overlapped in the top view Z of the electronic device. Similarly, even not shown in the figure, the second panel 2 may comprise plural pixel regions (not shown in the figure), and the second photoelectric conversion unit PSC2 and the pixel regions of the second panel 2 may be overlapped in the top view Z of the electronic device. Similarly, even not shown in the figure, the third panel 3 may comprise plural pixel regions (not shown in the figure), and the third photoelectric conversion unit PSC3 and the pixel regions of the third panel 3 may be overlapped in the top view Z of the electronic device. It should be noted that, in the first panel 1, plural areas formed by the intersection of the first electrode layer 12 and the second electrode layer 14 may be defined as the plural pixel regions (not shown in the figure) of the first panel 1; in the second panel 2, plural areas formed by the intersection of the third electrode layer 22 and the fourth electrode layer 24 may be defined as the plural pixel regions (not shown in the figure) of the second panel 2; and in the third panel 3, plural areas formed by the intersection of the fifth electrode layer 32 and the sixth electrode layer 34 may be defined as the plural pixel regions (not shown in the figure) of the third panel 3.

In one embodiment of the present disclosure, as shown in FIG. 1 and FIG. 2, the electronic device may further comprise another photoelectric conversion unit PSC4, wherein the first display layer 13 is disposed between the first photoelectric conversion unit PSC1 and the another photoelectric conversion unit PSC4. The another photoelectric conversion unit PSC4 may be used to absorb at least part of ultraviolet light, infrared light or a combination thereof and convert it into electrical energy. By disposing the another photoelectric conversion unit PSC4, the effect of photoelectric conversion can be improved to achieve power saving, or the damage of ultraviolet and infrared light to the electronic device can be reduced to improve the reliability of the electronic device. In the present disclosure, the another photoelectric conversion unit PSC4 may comprise a perovskite solar cell, a dye-sensitized solar cell or a combination thereof; but the present disclosure is not limited thereto.

In one embodiment of the present disclosure, as shown in FIG. 1 and FIG. 2, the electronic device may further comprise a light absorbing layer AL disposed adjacent to the third panel 3 (for example, the fifth substrate 31), and the third photoelectric conversion unit PSC3 is disposed between the third display layer 33 (or the fifth substrate 31) and the light absorbing layer AL; but the present disclosure is not limited thereto. In the present disclosure, the light absorbing layer AL may be used to absorb the light that is not absorbed by the first photoelectric conversion unit PSC1, the second photoelectric conversion unit PSC2 and/or the third photoelectric conversion unit PSC3, thereby improving the display quality of the electronic device. In one embodiment, the first photoelectric conversion unit PSC1, the second photoelectric conversion unit PSC2 and the third photoelectric conversion unit PSC3 can absorb part of the light that is not reflected by the above display layers to improve the color purity of the reflected light, and thus, in other embodiments, the light absorbing layer AL may be optionally omitted to save costs or reduce the overall thickness of the electronic device. In the present disclosure, the material of the light absorbing layer AL may comprise a black insulating layer, including such as a black organic material, a black inorganic material, a black ink, other suitable materials, or a combination thereof, but the present disclosure is not limited thereto.

In one embodiment of the present disclosure, as shown in FIG. 1 and FIG. 2, the first photoelectric conversion unit PSC1, the second photoelectric conversion unit PSC2 and the third photoelectric conversion unit PSC3 may respectively disposed outside the first panel 1, the second panel 2 and the third panel 3. More specifically, the first photoelectric conversion unit PSC1 may be disposed between the first panel 1 and the second panel 2, or the first photoelectric conversion unit PSC1 may be disposed between the first substrate 11 of the first panel 1 and the fourth substrate 25 of the second panel 2. The second photoelectric conversion unit PSC2 may be disposed between the second panel 2 and the third panel 3, or the second photoelectric conversion unit PSC2 may be disposed between the third substrate 21 of the second panel 2 and the sixth substrate 35 of the third panel 3. The third photoelectric conversion unit PSC3 may be disposed between the third panel 3 and the light absorbing layer AL, or the third photoelectric conversion unit PSC3 may be disposed between the fifth substrate 31 of the third panel 2 and the light absorbing layer AL; but the present disclosure is not limited thereto.

In one embodiment of the present disclosure, even not shown in the figure, adhesive layers (not shown in the figure) may be included between the another photoelectric conversion unit PSC4, the first panel 1, the first photoelectric conversion unit PSC1, the second panel 2, the second photoelectric conversion unit PSC2, the third panel 3, the third photoelectric conversion unit PSC3 and the light absorbing layer AL to adhere each components to form the electronic device of the present disclosure. In the present disclosure, the material of the adhesive layer (not shown in the figure) may comprise glass glue, optical glue, silicone glue, tape, hot melt glue, AB glue, two-component adhesive, polymer glue or a combination thereof, but the present disclosure is not limited thereto.

In one embodiment of the present disclosure, as shown in FIG. 1, the electronic device may further comprise an energy storage device E, electrically connected to the first photoelectric conversion unit PSC1, the second photoelectric conversion unit PSC2 and/or the third photoelectric conversion unit PSC3 respectively. The first photoelectric conversion unit PSC1, the second photoelectric conversion unit PSC2 and/or the third photoelectric conversion unit PSC3 may, for example, convert the above absorbed light into electrical energy, and the electrical energy may be stored in the energy storage device E. The another photoelectric conversion unit PSC4 may also be electrically connected to the energy storage device E, the another photoelectric conversion unit PSC4 may convert the above absorbed light into electrical energy, and the electrical energy may be stored in the energy storage device E.

In one embodiment of the present disclosure, as shown in FIG. 1, the electronic device may further comprise: a first drive circuit D1, a second drive circuit D2 and/or a third drive circuit D3, the first drive circuit D1 may be electrically connected to the energy storage device E and the first panel 1 respectively, the second drive circuit D2 may be electrically connected to the energy storage device E and the second panel 2 respectively, and the third drive circuit D3 may be electrically connected to the energy storage device E and the third panel 3 respectively; but the present disclosure is not limited thereto. The first drive circuit D1 may be electrically connected to the first electrode layer 12 and the second electrode layer 14 of the first panel 1 respectively, the second drive circuit D2 may be electrically connected to the third electrode layer 22 and the fourth electrode layer 24 of the second panel 2 respectively, and the third drive circuit D3 may be electrically connected to the fifth electrode layer 32 and the sixth electrode layer 34 of the third panel 3 respectively. In some embodiments, the drive circuits (for example, the first drive circuit D1, the second drive circuit D2 and the third drive circuit D3) may respectively receive the electrical energy provided by the energy storage device E, and provide the received electrical energy to the electrode layers of corresponding panels electrically connected thereto respectively, thereby driving the display layers of each panels corresponding thereto, so that the electronic device can displays an image. The first drive circuit D1, the second drive circuit D and the third drive circuit D3 may, for example, respectively comprise a scan driving circuit and a data driving circuit; but the present disclosure is not limited thereto. The scan driving circuit and the data driving circuit are, for example, used to respectively provide voltages to the electrode layers of different panels. The first drive circuit D1, the second drive circuit D and the third drive circuit D3 may be electrically connected to the above-mentioned panels through, for example, a chip on film (COF) package, a chip on glass (COG) package or other manners respectively.

An embodiment will be used as an example to describe in detail the situation in which light passes through an electronic device. However, the present disclosure is not limited to the following situation.

In one embodiment of the present disclosure, as shown in FIG. 2, the electronic device shown in FIG. 1 is used as an example. The first display layer 13 may comprise cholesteric texture liquid crystals that reflect left circularly polarized blue light, the second display layer 23 may comprise cholesteric texture liquid crystals that reflect left circularly polarized green light, and the third display layer 33 may comprise cholesteric texture liquid crystals that reflect left circularly polarized red light; but the present disclosure is not limited thereto. The first photoelectric conversion unit PSC1 may be used at least to absorb blue light (comprising left circularly polarized blue light and right circularly polarized blue light), the second photoelectric conversion unit PSC2 may be used at least to absorb green light (comprising left circularly polarized green light and right circularly polarized green light), the third photoelectric conversion unit PSC3 may be used at least to absorb red light (comprising left circularly polarized red light and right circularly polarized red light), and the another photoelectric conversion unit PSC4 may be used to absorb ultraviolet light and/or infrared light; but the present disclosure is not limited thereto. Even not shown in the electronic device, the electronic device of the present disclosure may comprise a display region (not shown in the figure) and a non-display region (not shown in the figure), the display region refers to the region in the display layer (for example, the first display layer 13, the second display layer 23 and the third display layer 33) that can reflect light. For example, the first display layer 13, the second display layer 23 and the third display layer 33 may comprise, for example, cholesteric texture liquid crystals. When the cholesteric texture liquid crystals corresponding to some pixel regions are in a reflective state, these pixel region can be defined as display regions. The non-display region refers to the region other than the display region. For example, the first display layer 13, the second display layer 23 and the third display layer 33 may comprise, for example, cholesteric texture liquid crystals. When the cholesteric texture liquid crystals corresponding to some pixel regions are in a scattering state (or a transmitting state), these pixel regions can be defined as non-display regions. For convenience of explanation, in FIG. 2, arrows are used to indicate the transmittance or reflection of light, where the transmitting light is indicated by a solid line and the reflected light is indicated by a dotted line. The light on the left side of the line L in FIG. 2 is left circularly polarized light, and the light on the right side of the line L is right circularly polarized light. What is represented by “O” in the table is the wavelength of light that the component can absorb.

As shown in FIG. 2, when ambient light (for example, comprising infrared light, ultraviolet light, red light, green light and/or blue light) irradiates onto the electronic device, the ultraviolet light (UV) and/or the infrared light (IR) may be, for example, at least partially absorbed by the another photoelectric conversion unit PSC4 and converted into electrical energy, and the unabsorbed light (for example, the red light (R), the green light (G) and the blue light (B)) may penetrate through the another photoelectric conversion unit PSC4. Thus, the another photoelectric conversion unit PSC4 can reduce ultraviolet light and/or infrared light from entering the following panels (such as the first panel 1, the second panel 2 and/or the third panel 3), and can be used to reduce the damage caused by ultraviolet light and infrared light to the electronic device.

Next, corresponding to the display region, the first display layer 13 may, for example, reflect the left circularly polarized blue light, and the unreflected light may penetrate through the first display layer 13, wherein the light not reflected by the first display layer 13 may comprise right circularly polarized blue light, green light (including left circularly polarized green light and right circularly polarized green light) and red light (including left circularly polarized red light and right circularly polarized red light). In the non-display region, red light (including left circularly polarized red light and right circularly polarized red light), green light (including left circularly polarized green light and right circularly polarized green light) and blue (including left circularly polarized blue light and right circularly polarized blue light) are not reflected by the first display layer 13, so most of them may penetrate through the first display layer 13. Then, the first photoelectric conversion unit PSC1 may absorb at least part of the blue light (B) and convert it into electrical energy, and the unabsorbed light (for example, red light (R) and green light (G)) may penetrate through the first photoelectric conversion unit PSC1. Thus, the first photoelectric conversion unit PSC1 can be used to improve the purity of reflected light.

Next, in the display region, the second display layer 23 may reflect the left circularly polarized green light, and the unreflected light may penetrate through the second display layer 23, wherein the light not reflected by the second display layer 23 may comprise right circularly polarized green light and red light (including left circularly polarized red light and right circularly polarized red light). In the non-display region, red light (including left circularly polarized red light and right circularly polarized red light) and green light (including left circularly polarized green light and right circularly polarized green light) are not reflected by the second display layer 23, so most of them may penetrate through the second display layer 23. Then, the second photoelectric conversion unit PSC2 may absorb at least part of the green light (G) and convert it into electrical energy, and the light that is not absorbed by the second photoelectric conversion unit PSC2 (for example, red light (R)) may penetrate through the second photoelectric conversion unit PSC2. Thus, the second photoelectric conversion unit PSC2 can be used to improve the purity of reflected light.

Next, in the display region, the third display layer 33 may reflect the left circularly polarized red light, and the unreflected light may penetrate through the third display layer 33, wherein the light that is not reflected by the third display layer 33 may be the right circularly polarized red light. In the non-display region, the red light (including the left circularly polarized red light and the right circularly polarized red light) are not reflected by the third display layer 33, and penetrate through the third display layer 33. Then, the third photoelectric conversion unit PSC3 may absorb at least part of the red light (R) and convert it into electrical energy. Thus, the third photoelectric conversion unit PSC3 can be used to improve the purity of reflected light and may have the same effect to the light absorbing layer AL. In some embodiments, when the above-mentioned light with different wavelengths or light with different colors can be absorbed by different photoelectric conversion units respectively, the light absorbing layer AL can be omitted.

It should be noted that, the above-mentioned first display layer 13, second display layer 23 and third display layer 33 are, for example, respectively used to reflect left circularly polarized light with different wavelengths, but the present disclosure is not limited thereto. In other embodiments (not shown in the figure), the first display layer 13, the second display layer 23 and the third display layer 33 may be used to reflect right circularly polarized light with different wavelengths.

In view above, in the electronic device of one embodiment of the present disclosure, images can be displayed by reflecting light with different colors through the first display layer 13, the second display layer 23, and the third display layer 33, and optionally no additional backlight module is required to form a reflective display device. In other embodiments, for example, the first panel 1 may be provided with a front light guide plate (not shown in the figure) and a light source (not shown in the figure) according to the needs. In addition, in the electronic device of the present disclosure, by using the first photoelectric conversion unit PSC1, the second photoelectric conversion unit PSC2, the third photoelectric conversion unit PSC3 and the another photoelectric conversion unit PSC4, the absorbed light can be converted into electrical energy respectively to achieve the effects of saving power, saving materials or reducing damage to the electronic device.

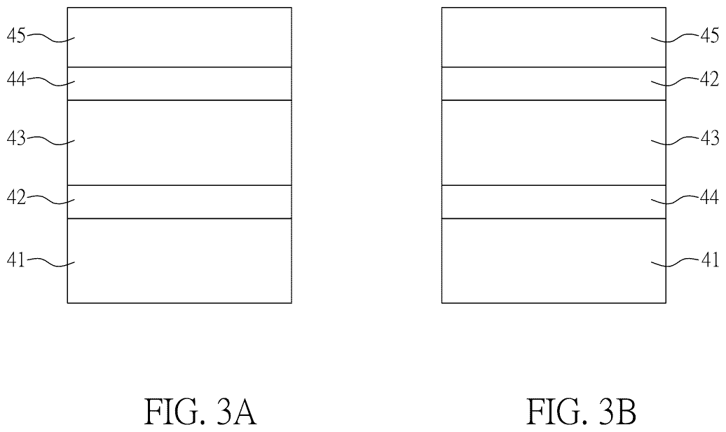

FIG. 3A and FIG. 3B respectively are schematic diagrams showing the photoelectric conversion units according to one embodiment of the present disclosure.

In one embodiment of the present disclosure, the first photoelectric conversion unit PSC1, the second photoelectric conversion unit PSC2, the third photoelectric conversion unit PSC3 and the another photoelectric conversion unit PSC4 may respectively comprise the structure of the perovskite solar cell shown in FIG. 3A or FIG. 3B; but the present disclosure is not limited thereto.

In one embodiment of the present disclosure, as shown in FIG. 3A, the perovskite solar cell may comprise: a conductive substrate 41; an electron transportation layer 42 disposed on the conductive substrate 41; a perovskite light absorbing layer 43 disposed on the electron transportation layer 42; a hole transportation layer 44 disposed on the perovskite light absorbing layer 43; and an electrode layer 45 disposed on the hole transportation layer 44, wherein the electron transportation layer 42 is disposed between the perovskite light absorbing layer 43 and the conductive substrate 41, the hole transportation layer 44 is disposed between the perovskite light absorbing layer 43 and the electrode layer 45, and the perovskite light absorbing layer 43 is disposed between the conductive substrate 41 and the electrode layer 45. Thus, FIG. 3A shows a perovskite solar cell with an n-i-p structure; but the present disclosure is not limited thereto.

In one embodiment of the present disclosure, as shown in FIG. 3B, the perovskite solar cell may comprise: a conductive substrate 41; a hole transportation layer 44 disposed on the conductive substrate 41; a perovskite light absorbing layer 43 disposed on the hole transportation layer 44; an electron transportation layer 42 disposed on the perovskite light absorbing layer 43; and an electrode layer 45 disposed on the electron transportation layer 42, wherein the hole transportation layer 44 is disposed between the perovskite light absorbing layer 43 and the conductive substrate 41, the electron transportation layer 42 is disposed between the perovskite light absorbing layer 43 and the electrode layer 45, and the perovskite light absorbing layer 43 is disposed between the conductive substrate 41 and the electrode layer 45. Thus, FIG. 3B shows a perovskite solar cell with a p-i-n structure; but the present disclosure is not limited thereto.

In the present disclosure, the conductive substrate 41 may comprise a glass substrate with fluorine-doped tin oxide (FTO), indium tin oxide (ITO), aluminum zinc oxide (AZO), indium zinc oxide (IZO) or a combination thereof formed thereon. In the present disclosure, the material of the electrode layer 45 may comprise a transparent conductive material, such as indium tin oxide (ITO), aluminum zinc oxide (AZO), indium zinc oxide (IZO) or a combination thereof; but the present disclosure is not limited thereto. In the present disclosure, the conductive substrate 41 and the electrode layer 45 may be respectively used as a top electrode and a bottom electrode of the perovskite solar cell; but the present disclosure is not limited thereto. In other embodiments, the conductive substrate 41 may be replaced by another substrate with another conductive layer. In the present disclosure, the perovskite light absorbing layer 43 may comprise perovskite having the formula ABX₃, wherein A may be, for example methylamine, ethylamine, formamidine, cesium (Cs) or rubidium (Rb); B may be, for example, lead, tin, titanium or germanium; and X may be, for example, halogen or oxygen; but the present disclosure is not limited thereto. The perovskite light absorbing layer 43 may use any suitable material.

In the present disclosure, the material of the electron transportation layer 42 may comprise: calcium, lithium fluoride, cesium carbonate, titanium oxide, zinc oxide, zirconium oxide, 2,9-methyl-4,7-diphenyl-1,10-phenanthroline (bathocuproine, BCP), poly[(9,9-bis(3′-(N,N-dimethylamino)propyl)-2,7-fluorine)-alt-2,7-(9,9-dioctylfluoride)](PFN), fullerene derivatives or a combination thereof; but the present disclosure is not limited thereto. In the present disclosure, the material of the hole transportation layer 44 may comprise: poly(3,4-ethylenedioxythiophene):polystyrenesulfonate (PEDOT:PSS), nickel oxide, molybdenum oxide, tungsten oxide, vanadium oxide, 2,2′,7,7′-tetrakis[N, N-bis(4-methoxyphenyl)amino]-9,9′-spirobifluorene (spiro-OMeTAD), N, N′-bis(3-methylphenyl)-N,N′-diphenyl-[1,1′-biphenyl]-4,4′-diamine (TPD), N,N′-diphenyl-N,N′-bis(4-methylphenyl)-4,4′-biphenyldiamine (PTPD), (poly(3-hexylthiophene-2,5-diyl, P3HT) or a combination thereof; but the present disclosure is not limited thereto.

In the present disclosure, even not shown in the figure, the perovskite solar cell shown in FIG. 3A and FIG. 3B may optionally further comprise other material layer respectively, and for example, may comprise a passivation layer, a hole blocking layer, an electron blocking layer, a hole injection layer, an electron injection layer or a combination thereof to improve the power conversion efficiency or stability of the perovskite solar cell.

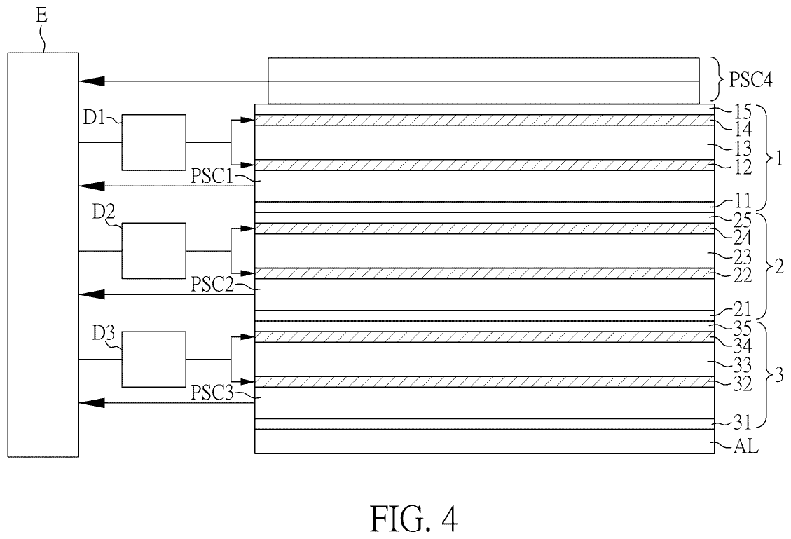

FIG. 4 is a schematic diagram of an electronic device according to one embodiment of the present disclosure. The electronic device in FIG. 4 is similar to that shown in FIG. 1, except for the following differences.

In one embodiment of the present disclosure, the photoelectric conversion units may be respectively disposed inside the panels. As shown in FIG. 4, the first photoelectric conversion unit PSC1 may be disposed inside the first panel 1, the second photoelectric conversion unit PSC2 may be disposed inside the second panel 2, and/or the third photoelectric conversion unit PSC3 may be disposed inside the third panel 3. More specifically, the first photoelectric conversion unit PSC1 may be disposed between the first substrate 11 and the first electrode layer 12, the second photoelectric conversion unit PSC2 may be disposed between the third substrate 21 and the third electrode layer 22, or the third photoelectric conversion unit PSC3 may be disposed between the fifth substrate 31 and the fifth electrode layer 32; but the present disclosure is not limited thereto. Even not shown in the figure, the first photoelectric conversion unit PSC1 may be disposed inside the second panel 2, and the second photoelectric conversion unit PSC2 may be disposed inside the third panel 3. More specifically, the first photoelectric conversion unit PSC1 may be disposed between the fourth substrate 25 and the fourth electrode layer 24, and the second photoelectric conversion unit PSC2 may be disposed between the sixth substrate 35 and the sixth electrode layer 34; but the present disclosure is not limited thereto. Even not shown in the figure, the another photoelectric conversion unit PSC4 may be disposed inside the first panel 1, and the another photoelectric conversion unit PSC4 may be disposed between the second substrate 15 and the second electrode layer 14.

In one embodiment of the present disclosure, even not shown in the figure, adhesive layers may be respectively disposed between the another photoelectric conversion unit PSC4, the first panel 1, the second panel 2 and the third panel 3 to adhere each components to form the electronic device of the present disclosure.

In the present embodiment, the aspects, types, materials, etc. of each component can be as described above and will not be described again here.

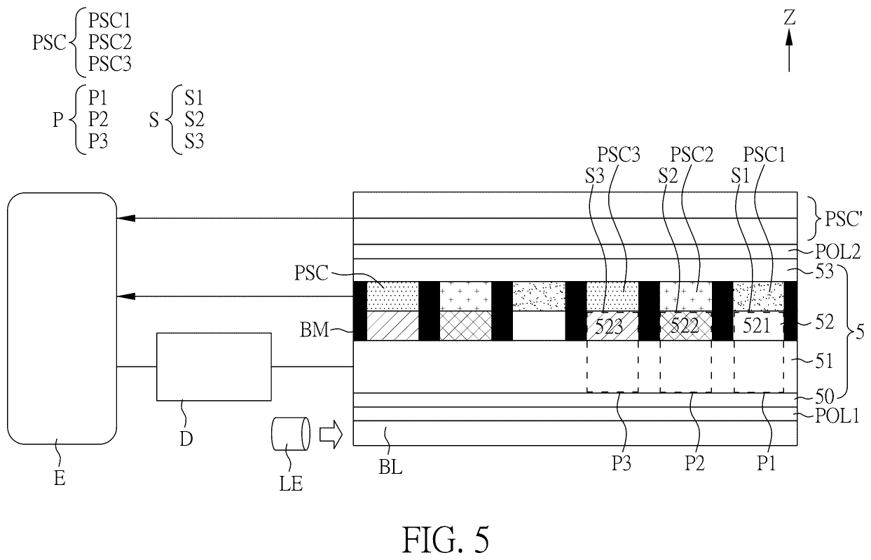

FIG. 5 is a schematic diagram of an electronic device according to one embodiment of the present disclosure.

In one embodiment of the present disclosure, as shown in FIG. 5, the electronic device may comprise: a panel 5 comprising: a plurality of pixel units P (for example, a first pixel unit P1, a second pixel unit P2 and/or a third pixel unit P3) respectively having a first side S, wherein the first pixel unit P1, the second pixel unit P2 and/or the third pixel unit P3 respectively emit different display lights and emit from the first side S; and a plurality of photoelectric conversion units PSC (for example, a first photoelectric conversion unit PSC1, a second photoelectric conversion unit PSC2 and/or a third photoelectric conversion unit PSC3), wherein the first photoelectric conversion unit PSC1 is adjacent to the first side S1 of the first pixel unit P1, the second photoelectric conversion unit PSC2 is adjacent to the first side S2 of the second pixel unit P2, and the third photoelectric conversion unit PSC3 is adjacent to the first side S3 of the third pixel unit P3. Herein, the first photoelectric conversion unit PSC1 absorbs at least part of the display light emitted from the first pixel unit P1 and converts it into electrical energy, the second photoelectric conversion unit PSC2 absorbs at least part of the display light emitted from the second pixel unit P2 and converts it into electrical energy, and the third photoelectric conversion unit PSC3 absorbs at least part of the display light emitted from the third pixel unit P3 and converts it into electrical energy. The plurality of photoelectric conversion units PSC (for example, the first photoelectric conversion unit PSC1, the second photoelectric conversion unit PSC2 and/or the third photoelectric conversion unit PSC3) disposed in the electronic device may respectively absorb at least part of the display lights emitted from the pixel units corresponding thereto and convert it into electrical energy for the use of the electronic device, so the power saving and improving color purity can be achieved.

In one embodiment of the present disclosure, as shown in FIG. 5, the panel 5 may comprise a display layer 51 and a light conversion layer 52, wherein the light conversion layer 52 is disposed between the display layer 51 and the photoelectric conversion unit PSC. The light conversion layer 52 may comprise a plurality of light conversion units, and each light conversion unit may be respectively disposed corresponding to one of the photoelectric conversion units PSC. The plurality of light conversion units may comprise a first light conversion unit 521, a second light conversion unit 522 and a third light conversion unit 523, the plurality of photoelectric conversion units PSC may comprise a first photoelectric conversion unit PSC1, a second photoelectric conversion unit PSC2 and a third photoelectric conversion unit PSC3. The first light conversion unit 521 may be disposed corresponding to the first photoelectric conversion unit PSC1, the second light conversion unit 522 may be disposed corresponding to the second photoelectric conversion unit PSC2, and the third light conversion unit 523 may be disposed corresponding to the third photoelectric conversion unit PSC3. The light conversion unit may selectively absorb light with specific colors or wavelengths and convert it into light with other colors or wavelengths. The “a component disposed corresponding to another component” means that a component and another component are overlapped in a top view Z of the electronic device. For example, “a first light conversion unit disposed corresponding to a first photoelectric conversion unit” means that the first light conversion unit 521 and the first photoelectric conversion unit PSC1 are overlapped in the top view Z of the electronic device. In one embodiment of the present disclosure, each pixel unit (for example, as shown in the dotted box in FIG. 5) may comprise, for example, the light conversion unit and a part of the display layer 51 corresponding thereto; but the present disclosure is not limited thereto. The first pixel unit P1 may comprise, for example, the first light conversion unit 521 and the part of the display layer 51 corresponding thereto. The second pixel unit P2 may comprise, for example, the second light conversion unit 522 and the part of the display layer 51 corresponding thereto. The third pixel unit P3 may comprise, for example, the third light conversion unit 523 and the part of the display layer 51 corresponding thereto. In one embodiment of the present disclosure, each light conversion unit may be disposed between the part of the display layer corresponding thereto and the photoelectric conversion unit PSC. For example, the first light conversion unit 521 may be disposed between the part of the display layer 51 corresponding thereto and the first photoelectric conversion unit PSC1, the second light conversion unit 522 may be disposed between the part of the display layer 51 corresponding thereto and the second photoelectric conversion unit PSC2, and the third light conversion unit 523 may be disposed between the part of the display layer 51 corresponding thereto and the third photoelectric conversion unit PSC3. In other embodiments, the display layer 51 may not be formed into an entire surface, that is, the display layer 51 located in different pixel units may be, for example, separated from each other.

In one embodiment of the present disclosure, the panel 5 may comprise a substrate 50 and a counter substrate 53 opposite to each other. The plurality of pixel units P (for example, the first pixel unit P1, the second pixel unit P2 and/or the third pixel unit P3) are disposed between the substrate 50 and the counter substrate 53. Even not shown in the figure in detail, the display layer 51 may comprise an electrode layer (not shown in the figure), an active unit (not shown in the figure), a conductive line (not shown in the figure), a display medium (not shown in the figure), an alignment layer (not shown in the figure), an insulating layer (not shown in the figure) or a combination thereof; but the present disclosure is not limited thereto. In the present disclosure, the display medium may include liquid crystal materials or other display media materials; but the present disclosure is not limited thereto.

As shown in FIG. 5, each light conversion unit and the part of the display layer corresponding thereto form a pixel unit P. For example, the first light conversion unit 521 and the part of the display layer 51 corresponding thereto form a first pixel unit P1, the second light conversion unit 522 and the part of the display layer 51 corresponding thereto form a second pixel unit P2, and the third light conversion unit 523 and the part of the display layer 51 corresponding thereto form a third pixel unit P3. The plurality of pixel units P may comprise, for example, the first pixel unit P1, the second pixel unit P2 and the third pixel unit P3; but the present disclosure is not limited thereto. The first pixel unit P1 has a first side S1, the second pixel unit P2 has a first side S2, the third pixel unit P3 has a first side S3, the display light emitted from the first pixel unit P1 may be emitted from the first side S1, the display light emitted from the second pixel unit P2 may be emitted from the first side S2, and the display light emitted from the third pixel unit P3 may be emitted from the first side S3; but the present disclosure is not limited thereto. The “first side” refers to the side of the pixel unit P adjacent to the photoelectric conversion element PSC corresponding thereto. In one embodiment of the present disclosure, the first side S of the pixel unit P may refer to, for example, the upper surface of the corresponding light conversion layer 52; but the present disclosure is not limited thereto.

In one embodiment of the present disclosure, as shown in FIG. 5, the plurality of photoelectric conversion elements PSC may be disposed adjacent to the first side S respectively. For example, the first photoelectric conversion unit PSC1 may be disposed adjacent to the first side S1 of the first pixel unit P1, the second photoelectric conversion unit PSC2 may be disposed adjacent to the first side S2 of the second pixel unit P2, and the third photoelectric conversion unit PSC3 may be disposed adjacent to the first side S3 of the third pixel unit P3; but the present disclosure is not limited thereto. In one embodiment of the present disclosure, as shown in FIG. 5, the first pixel unit P1 may be disposed corresponding to the first photoelectric conversion unit PSC1, the second pixel unit P2 may be disposed corresponding to the second photoelectric conversion unit PSC2, and the third pixel unit P3 may be disposed corresponding to the third photoelectric conversion unit PSC3; but the present disclosure is not limited thereto.

In the present disclosure, the wavelength ranges of light absorbed by the first photoelectric conversion unit PSC1, the second photoelectric conversion unit PSC2 and the third photoelectric conversion unit PSC3 are different. For example, the first photoelectric conversion unit PSC1 may absorb visible light outside the blue light wavelength range, the second photoelectric conversion unit PSC2 may absorb visible light outside the green light wavelength range, and the third photoelectric conversion unit PSC3 may absorb visible light outside the red light wavelength range; but the present disclosure is not limited thereto. Therefore, the first photoelectric conversion unit PSC1 may allow, for example, most of the blue light to pass through, the second photoelectric conversion unit PSC2 may allow, for example, most of the green light to pass through, and the third photoelectric conversion unit PSC3 may allow, for example, most of the red light to pass through; but the present disclosure is not limited thereto. In the present disclosure, the plurality of photoelectric conversion units PSC (for example, the first photoelectric conversion unit PSC1, the second photoelectric conversion unit PSC2 and the third photoelectric conversion unit PSC3) may have the function of a filter layer, so the filter layer may be optionally omitted in the electronic device to save materials. In addition, in the present disclosure, the plurality of photoelectric conversion units PSC (for example, the first photoelectric conversion unit PSC1, the second photoelectric conversion unit PSC2 and the third photoelectric conversion unit PSC3), for example, may not have polarizing properties. The “not have polarizing properties” means that these photoelectric conversion units PSC do not specifically absorb light in a certain polarization direction, and these photoelectric conversion units PSC (for example, the first photoelectric conversion unit PSC1, the second photoelectric conversion unit PSC2 and the third photoelectric conversion unit PSC3) may absorbed light with multiple polarization directions.

In one embodiment of the present disclosure, as shown in FIG. 5, the electronic device may further comprise a backlight module BL, and the panel 5 is disposed on the backlight module BL. The backlight module BL is used to provide light to the plurality of pixel units P (for example, the first pixel unit P1, the second pixel unit P2 and the third pixel unit P3), so the plurality of pixel units P (for example, the first pixel unit P1, the second pixel unit P2 and the third pixel unit P3) may respectively emit different display lights. More specifically, the backlight module BL may provide light (for example, blue light) to the plurality of pixel units P (for example, the first pixel unit P1, the second pixel unit P2 and the third pixel unit P3), and the light conversion units in the pixel units P may selectively convert the light (for example, blue light) into corresponding color light. For example, the first light conversion unit 521 may, for example, selectively convert the blue light into blue light with other wavelength range, or the first light conversion unit 521 may be replaced by other optical unit (for example, a light scattering layer) and does not have the function of light conversion. The second light conversion unit 522 may, for example, convert the blue light into green light, and the third light conversion unit 523 may convert the blue light into red light. Therefore, the first pixel unit P1, the second pixel unit P2 and the third pixel unit P3 may respectively emit display lights with different colors so that the electronic device can display an image. The aforesaid light conversion units may include quantum dots, phosphors, fluorescence, other suitable light conversion materials, or a combination thereof.

In addition, even not shown in the figure in detail, the backlight module BL may comprise a frame, a light-emitting element LE, a light guide plate, a reflective plate, an optical film or a combination thereof; but the present disclosure is not limited thereto. In the present disclosure, the light-emitting element LE may comprise a light emitting diode, and the light emitting diode may comprise, for example, an organic light emitting diode (OLED), a mini LED, a micro LED or a quantum dot LED (including QLED or QDLED), fluorescence, phosphors, other suitable materials or a combination thereof; but the present disclosure is not limited thereto. In one embodiment of the present disclosure, the light-emitting element LE may provide blue light or ultraviolet light; but the present disclosure is not limited thereto. In the present disclosure, the material of the reflective plate may comprise, for example, a metal or white reflective material layer, other reflective materials or a combination thereof. In the present disclosure, the optical film may comprise a brightening film, a diffusion film, other suitable optical film or a combination thereof; but the present disclosure is not limited thereto.

In the present disclosure, the plurality of photoelectric conversion units PSC (for example, the first photoelectric conversion unit PSC1, the second photoelectric conversion unit PSC2 and the third photoelectric conversion unit PSC3) may respectively comprise a perovskite solar cell, a dye-sensitized solar cell or a combination thereof; but the present disclosure is not limited thereto. In one embodiment of the present disclosure, the plurality of photoelectric conversion units PSC (for example, the first photoelectric conversion unit PSC1, the second photoelectric conversion unit PSC2 and the third photoelectric conversion unit PSC3) may respectively comprise a perovskite solar cell, and the structure of the perovskite solar cell may be as shown in FIG. 3A or FIG. 3B which is not described again here. In the present disclosure, the light conversion layer 52 may selectively comprise quantum dot materials. For example, the first light conversion unit 521 may not comprise the quantum dot materials, but the second light conversion unit 522 and the third light conversion unit 523 may respectively comprise the quantum dot materials; but the present disclosure is not limited thereto. In one embodiment of the present disclosure, the first light conversion unit 521 may selectively comprise a scattering material to improve the light emitting efficiency; but the present disclosure is not limited thereto.

In one embodiment of the present disclosure, as shown in FIG. 5, the counter substrate 53 of the panel 5 is disposed on the first photoelectric conversion unit PSC1, the second photoelectric conversion unit PSC2 and the third photoelectric conversion unit PSC3. The first photoelectric conversion unit PSC1 is disposed between the first pixel unit P1 and the counter substrate 53, the second photoelectric conversion unit PSC2 is disposed between the second pixel unit P2 and the counter substrate 53, and the third photoelectric conversion unit PSC3 is disposed between the third pixel unit P3 and the counter substrate 53. In other words, the first photoelectric conversion unit PSC1, the second photoelectric conversion unit PSC2 and/or the third photoelectric conversion unit PSC3 may be, for example, respectively disposed inside the panel 5. In one embodiment of the present disclosure, even not shown in the figure, the counter substrate 53 of the panel 5 may also be disposed between pixel units P and the first photoelectric conversion unit PSC1, the second photoelectric conversion unit PSC2 and/or the third photoelectric conversion unit PSC3. In other words, the first photoelectric conversion unit PSC1, the second photoelectric conversion unit PSC2 and/or the third photoelectric conversion unit PSC3 may be, for example, disposed outside the panel 5. For example, the first photoelectric conversion unit PSC1, the second photoelectric conversion unit PSC2 and/or the third photoelectric conversion unit PSC3 may be, for example, respectively disposed between the counter substrate 53 and the second polarizer POL2; but the present disclosure is not limited thereto.

In one embodiment of the present disclosure, as shown in FIG. 5, the electronic device may further comprise another photoelectric conversion unit PSC′ disposed on the panel 5 and overlapped with the first pixel unit P1, the second pixel unit P2 and the third pixel unit P3, wherein a wavelength range of light absorbed by the another photoelectric conversion unit PSC′ is different from the wavelength ranges of the light absorbed by the first photoelectric conversion unit PSC1, the second photoelectric conversion unit PSC2 and/or the third photoelectric conversion unit PSC3. For example, the another photoelectric conversion unit PSC′ may absorb at least part of ultraviolet light wavelength, infrared light wavelength or a combination thereof and covert it into electrical energy. The setting of the another photoelectric conversion unit PSC′ can improve the photoelectric conversion effect to achieve power saving, or it can reduce the damage of ultraviolet and/or infrared light to the electronic device and improve the reliability of the electronic device. In the present disclosure, the another photoelectric conversion unit PSC′ may be the same as or different from the first photoelectric conversion unit PSC1, the second photoelectric conversion unit PSC2 and the third photoelectric conversion unit PSC3, and the another photoelectric conversion unit PSC′ may contain at least one or multiple layers of solar cells, and for example, comprise a perovskite solar cell, a dye-sensitized solar cell or a combination thereof; but the present disclosure is not limited thereto.

In one embodiment of the present disclosure, as shown in FIG. 5, the electronic device may comprise a first polarizer POL1 and a second polarizer POL2, the first polarizer POL1 is disposed between the backlight module BL and the panel 5, and the second polarizer POL2 is disposed between the panel 5 and the another photoelectric conversion unit PSC′. However, the present disclosure is not limited thereto, and the positions of the first polarizer POL1 and the second polarizer POL2 may be adjusted according to the needs.

In one embodiment of the present disclosure, as shown in FIG. 5, a black matrix layer BM (or other separation material layer) may be selectively disposed between adjacent light conversion units. For example, a black matrix layer BM (or other separation material layer) may be disposed between the first light conversion unit 521, the second light conversion unit 522 and the third light conversion unit 523. The black matrix layer BM (or other separation material layer) may reduce light mixing between adjacent pixel units and improve the display quality. In one embodiment of the present disclosure, as shown in FIG. 5, a black matrix layer BM (or other separation material layer) may be disposed between adjacent photoelectric conversion units, for example, a black matrix layer BM (or other separation material layer) may be disposed between the first photoelectric conversion unit PSC1, the second photoelectric conversion unit PSC2 and the third photoelectric conversion unit PSC3; but the present disclosure is not limited thereto. In the present disclosure, the material of the black matrix layer BM may comprise a black ink layer, a black resin layer, an anti-reflective material or a light-absorbing material; but the present disclosure is not limited thereto. Other separation material layer may comprise other suitable anti-reflective material or light-absorbing material.

In one embodiment of the present disclosure, as shown in FIG. 5, the electronic device may further comprise an energy storage device E electrically connected to the first photoelectric conversion unit PSC1, the second photoelectric conversion unit PSC2, the third photoelectric conversion unit PSC3 and the another photoelectric conversion unit PSC′ respectively. The first photoelectric conversion unit PSC1, the second photoelectric conversion unit PSC2, the third photoelectric conversion unit PSC3 and the another photoelectric conversion unit PSC′ may absorb light with the aforesaid wavelengths and convert it into electrical energy, and the electrical energy may be stored in the energy storage device E.

In one embodiment of the present disclosure, as shown in FIG. 5, the electronic device may further comprise a driving circuit D, and the driving circuit D may be electrically connected to the energy storage device E and the panel 5 respectively. The driving circuit D may receive the electrical energy provided by the energy storage device E and apply to the panel 5 to drive the display layer 51, so that the electronic device can display an image. The detail of the driving circuit D can be referred to the above.

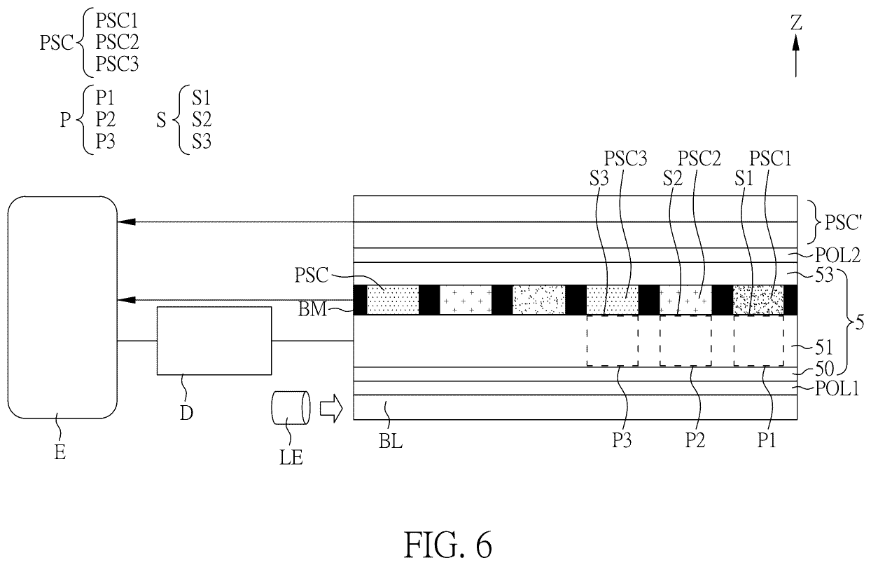

FIG. 6 is a schematic diagram of an electronic device according to one embodiment of the present disclosure. The electronic device shown in FIG. 6 is similar to that shown in FIG. 5, except for the following differences.

In one embodiment of the present disclosure, as shown in FIG. 6, the light provided by the light-emitting element LE may be white light, so the light conversion layer 52 (as shown in FIG. 5) in the panel 5 can be omitted. More specifically, the panel 5 may comprise a display layer 51, the display layer 51 may form a plurality of pixel units P (as shown by the dotted lines), for example, the first pixel unit P1, the second pixel unit P2 and the third pixel unit P3; but the present disclosure is not limited thereto. The detail of the display layer 51 can refer to the description of FIG. 5. The plurality of pixel units P may respectively have a first side S. For example, the first pixel unit P1 has a first side S1, the second pixel unit P2 has a first side S2, and the third pixel unit P3 has a first side S3; but the present disclosure is not limited thereto. In one embodiment of the present disclosure, as shown in FIG. 6, the first side S of the pixel unit P may be, for example, the upper surface of the display layer 51; but the present disclosure is not limited thereto. In addition, the first pixel unit P1 may be disposed corresponding to the first photoelectric conversion unit PSC1, the second pixel unit P2 may be disposed corresponding to the second photoelectric conversion unit PSC2, and the third pixel unit P3 may be disposed corresponding to the third photoelectric conversion unit PSC3.

In the present disclosure, the first photoelectric conversion unit PSC1 may be, for example, used to absorb the visible light outside the blue light wavelength range, the second photoelectric conversion unit PSC2 may be, for example, used to absorb the visible light outside the green light wavelength range, and the third photoelectric conversion unit PSC3 may be, for example, used to absorb the visible light outside the red light wavelength range. Thus, first photoelectric conversion unit PSC1 may, for example, allow most blue light to pass through, the second photoelectric conversion unit PSC2 may, for example, allow most green light to pass through, and the third photoelectric conversion unit PSC3 may, for example, allow most red light to pass through; but the present disclosure is not limited thereto. Therefore, in the present disclosure, the plurality of photoelectric conversion units PSC have the function of a filter layer, so the filter layer can be selectively omitted in the electronic device to achieve the effect of material saving.

In one embodiment of the present disclosure, as shown in FIG. 6, the counter substrate 53 may be disposed on the photoelectric conversion units PSC, wherein the first photoelectric conversion unit PSC1, the second photoelectric conversion unit PSC2 and the third photoelectric conversion unit PSC3 are disposed between the counter substrate 53 and the display layer 51 (i.e. the pixel units). The first photoelectric conversion unit PSC1 is disposed between the first pixel unit P1 and the counter substrate 53, the second photoelectric conversion unit PSC2 is disposed between the second pixel unit P2 and the counter substrate 53, and the third photoelectric conversion unit PSC3 is disposed between the third pixel unit P3 and the counter substrate 53. In other words, the first photoelectric conversion unit PSC1, the second photoelectric conversion unit PSC2 and the third photoelectric conversion unit PSC3 may be disposed inside the panel 5 respectively. Even not shown in the figure, similar to the description related to FIG. 5, the counter substrate 53 may also be disposed between the display layer 51 and the first photoelectric conversion unit PSC1, the second photoelectric conversion unit PSC2 and the third photoelectric conversion unit PSC3. In other words, the first photoelectric conversion unit PSC1, the second photoelectric conversion unit PSC2 and the third photoelectric conversion unit PSC3 may be disposed outside the panel 5 respectively.

In the present disclosure, the dispositions and materials of other components in the electronic device of FIG. 6 can be as those described related to FIG. 5 and will not be described again.

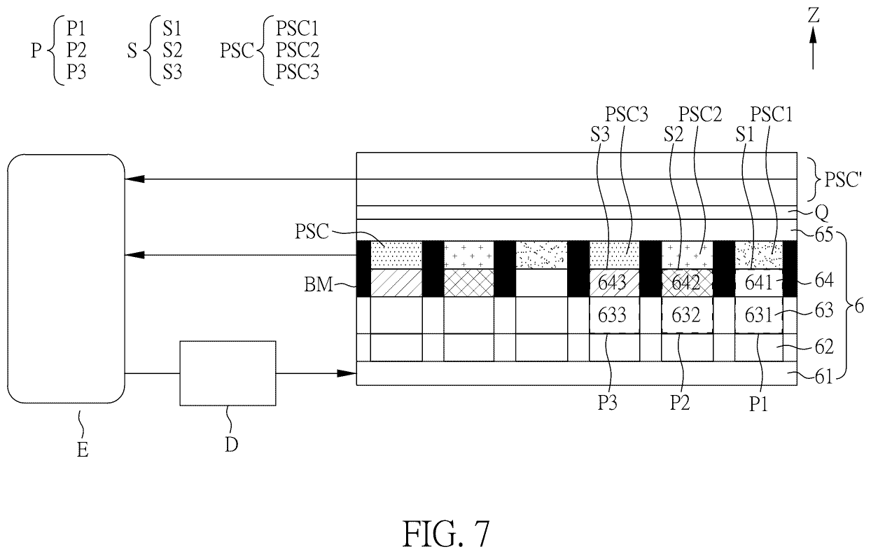

FIG. 7 is a schematic diagram of an electronic device according to one embodiment of the present disclosure. The electronic device shown in FIG. 7 is similar to that shown in FIG. 5, except for the following differences.

In one embodiment of the present disclosure, the electronic device may be a self-luminous display device. Thus, as shown in FIG. 7, the electronic device does not require additional backlight module BL (as shown in FIG. 5). Therefore, in one embodiment of the present disclosure, the electronic device may comprise: a panel 6 comprising a substrate 61; a counter substrate 65 disposed opposite to the substrate 61; an active layer 62 (for example, including at least one transistor) disposed on the substrate 61; a display layer 63 disposed on the active layer 62; and a light conversion layer 64 disposed on the display layer 63, wherein the display layer 63 and the light conversion layer 64 may, for example, for a plurality of pixel units P, but the present disclosure is not limited thereto, the plurality of pixel units P may respectively have a first side S, and the plurality of pixel units P may respectively emit a plurality of display lights which respectively emit from the first sides S; and a plurality of photoelectric conversion units PSC respectively disposed adjacent to the first sides S. More specifically, each pixel unit P may comprise a display unit 63 (or a light emitting unit) and a light conversion unit 64. For example, the first pixel unit P1 comprises a first display unit 631 and a first light conversion unit 641, the second pixel unit P2 comprises a second display unit 632 and a second light conversion unit 642, and the third pixel unit P3 comprises a third display unit 633 and a third light conversion unit 643; but the present disclosure is not limited thereto. The first light conversion unit 641 is disposed between the first display unit 631 and the first photoelectric conversion unit PSC1, the second light conversion unit 642 is disposed between the second display unit 632 and the second photoelectric conversion unit PSC2, and the third light conversion unit 643 is disposed between the third display unit 633 and the third photoelectric conversion unit PSC3.

In the present disclosure, the material of the substrate 61 or the counter substrate 65 may comprise a rigid substrate or a flexible substrate, and the detail thereof may be referred to the above. In one embodiment of the present disclosure, even not shown in the figure in detail, the display layer 63 may comprise an electrode layer, a display medium, an insulating layer or a combination thereof; but the present disclosure is not limited thereto. In the present disclosure, the display medium may comprise an organic light emitting diode or an inorganic light emitting diode.

In one embodiment of the present disclosure, the display layer 63 may, for example, provide blue light, and the light conversion unit 64 may selectively convert the blue light into light with corresponding color, and for example, the first light conversion unit 641 may selectively convert the blue light into blue light with other wavelengths; or the light conversion unit 641 may be, for example, replaced by other optical unit (for example, a light scattering layer). The second light conversion unit 642 may convert the blue light into green light, and the third light conversion unit 643 may convert the blue light into red light. Thus, the first pixel unit P1, the second pixel unit P2 and the third pixel unit P3 may respectively emit display lights with different colors. The above colors of the light converted by the light conversion unit are used as an example, and may be adjusted according to the needs. In addition, the first photoelectric conversion unit PSC1 may be, for example, used to absorb visible light outside the blue light wavelength range, the second photoelectric conversion unit PSC2 may be, for example, used to absorb visible light outside the green light wavelength range, and the third photoelectric conversion unit PSC3 may be, for example, used to absorb visible light outside the red light wavelength range. Thus, the first photoelectric conversion unit PSC1 may, for example, allow most or at least part of blue light to pass through, the second photoelectric conversion unit PSC2 may, for example, allow most or at least part of green light to pass through, and the third photoelectric conversion unit PSC3 may, for example, allow most or at least part of red light to pass through. Thus, in the present disclosure, the above photoelectric conversion units can have the function of a filter layer, and the filter layer can be selectively omitted in the electronic device, thereby achieving the effect of material saving. The above photoelectric conversion units PSC may absorb light with different wavelengths and converts the light into electrical energy, which can be stored in the energy storage device E and subsequently provided to the driving circuit D for use, thereby saving power consumption.

In one embodiment of the present disclosure, as shown in FIG. 7, the electronic device may further comprise an optical component Q (for example, a quarter-wave plate) disposed on the counter substrate 65, wherein the counter substrate 65 may be disposed between the optical component Q (for example, a quarter-wave plate or other phase delay films) and the display layer 63. In one embodiment of the present disclosure, as shown in FIG. 7, the photoelectric conversion unit PSC is disposed between the counter substrate 65 and the display layer 63. In other words, the first photoelectric conversion unit PSC1, the second photoelectric conversion unit PSC2 and/or the third photoelectric conversion unit PSC3 may be respectively disposed inside the panel 6.

In the present disclosure, other components and materials in the electronic device of FIG. 7 can be as those described related to FIG. 5 and will not be described again here.

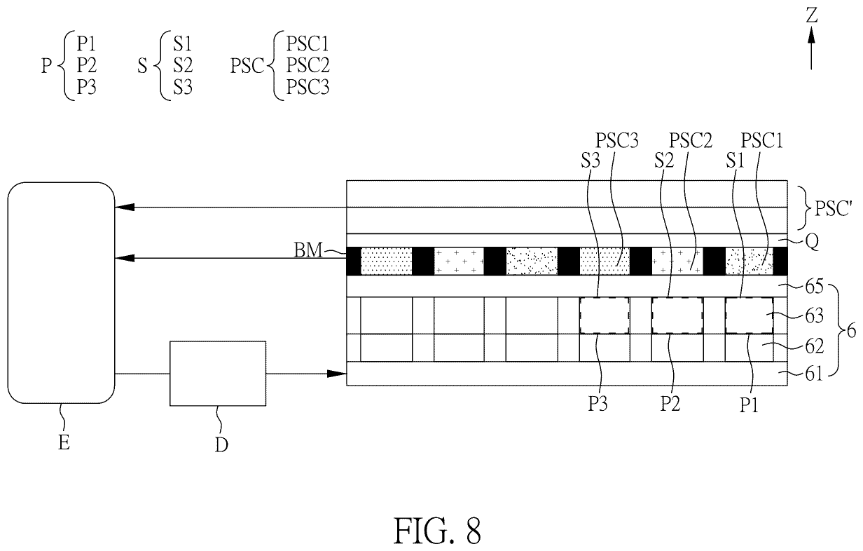

FIG. 8 is a schematic diagram of an electronic device according to one embodiment of the present disclosure. The electronic device shown in FIG. 8 is similar to that shown in FIG. 7, except for the following differences.

In one embodiment of the present disclosure, as shown in FIG. 8, the light provided by the display layer 63 may be white light, and the light conversion layer 64 (for example, the first light conversion unit 641, the second light conversion unit 642 and the third light conversion unit 643 as shown in FIG. 7) may be omitted in the panel 6. More specifically, the panel 6 may comprise a display layer 63, and the display layer 63 may form a plurality of pixel units P, for example, the first pixel unit P1, the second pixel unit P2 and the third pixel unit P3; but the present disclosure is not limited thereto. The plurality of pixel units P may respectively have a first side S. For example, the first pixel unit P1 has a first side S1, the second pixel unit P2 has a first side S2, and the third pixel unit P3 has a first side S3; but the present disclosure is not limited thereto. In one embodiment of the present disclosure, as shown in FIG. 8, the first side S of the pixel unit P may, for example, refer to the upper surface of the display layer 63; but the present disclosure is not limited thereto.

In the present disclosure, the first photoelectric conversion unit PSC1 may be, for example, used to absorb visible light outside the blue light wavelength range, the second photoelectric conversion unit PSC2 may be, for example, used to absorb visible light outside the green light wavelength range, and the third photoelectric conversion unit PSC3 may be, for example, used to absorb visible light outside the red light wavelength range. Thus, the first photoelectric conversion unit PSC1 may, for example, allow most or at least part of the blue light to pass through, the second photoelectric conversion unit PSC2 may, for example, allow most or at least part of the green light to pass through, and the third photoelectric conversion unit PSC3 may, for example, allow most or at least part of the red light to pass through; but the present disclosure is not limited thereto. Therefore, in the present disclosure, the photoelectric conversion unit can have the function of a filter layer, and the filter layer can be selectively omitted in the electronic device to achieve the effect of material saving.

In one embodiment of the present disclosure, as shown in FIG. 8, the counter substrate 65 may be disposed between the photoelectric conversion units PSC (for example, the first photoelectric conversion unit PSC1, the second photoelectric conversion unit PSC2 and the third photoelectric conversion unit PSC3) and the display layer 63. In other words, the above photoelectric conversion units PSC may be respectively disposed outside the panel 6. In addition, the first pixel unit P1 may be disposed corresponding to the first photoelectric conversion unit PSC1, the second pixel unit P2 may be disposed corresponding to the second photoelectric conversion unit PSC2, and the third pixel unit P3 may be disposed corresponding to the third photoelectric conversion unit PSC3. The photoelectric conversion units PSC (for example, the first photoelectric conversion unit PSC1, the second photoelectric conversion unit PSC2 and the third photoelectric conversion unit PSC3) may be respectively disposed between an optical component Q (for example, a quarter-wave plate) and the counter substrate 65. In one embodiment of the present disclosure, as shown in FIG. 8, the electronic device may further comprise another photoelectric conversion unit PSC″ disposed on the panel 6 and overlapped with the first pixel unit P1, the second pixel unit P2 and the third pixel unit P3, wherein the wavelength range of the light absorbed by the another photoelectric conversion unit PSC″ is different from the wavelength ranges of the light absorbed by the first photoelectric conversion unit PSC1, the second photoelectric conversion unit PSC2 and the third photoelectric conversion unit PSC3. For example, the another photoelectric conversion unit PSC″ may absorb at least part of ultraviolet light, at least part of infrared light or a combination thereof and convert it into electrical energy. The disposition of the another photoelectric conversion unit PSC″ can improve the effect of photoelectric conversion to save power, or reduce the damage of ultraviolet and/or infrared light to the electronic device, improving the reliability of the electronic device.

In the present disclosure, other components and materials in the electronic device of FIG. 8 can be as those described related to FIG. 7 and will not be described again here.

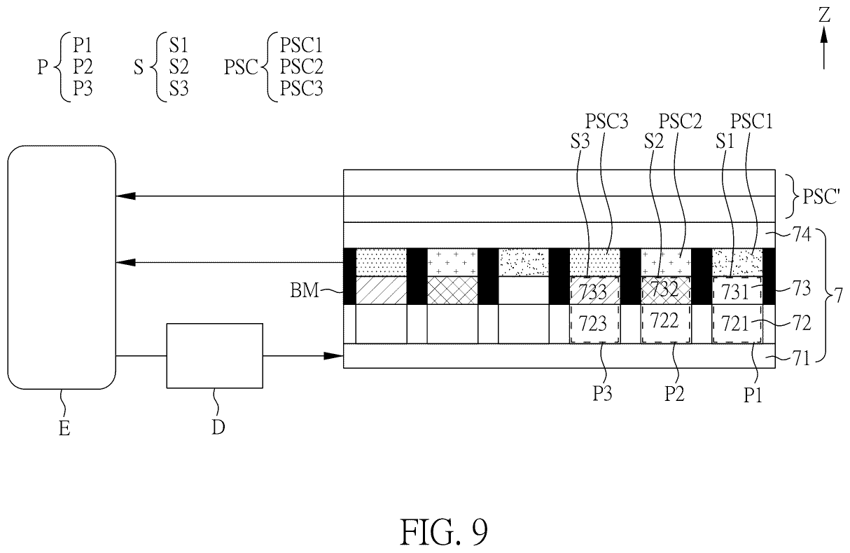

FIG. 9 is a schematic diagram of an electronic device according to one embodiment of the present disclosure. The electronic device shown in FIG. 9 is similar to that shown in FIG. 5, except for the following differences.

In one embodiment of the present disclosure, the electronic device may be a self-luminous display device. Thus, as shown in FIG. 9, the backlight module BL (as shown in FIG. 5) is not additionally required in the electronic device. Therefore, in one embodiment of the present disclosure, the electronic device may comprise: a panel 7 comprising: a substrate 71; a counter substrate 74 disposed opposite ot the substrate 71; a display layer 72 disposed on the substrate 71; and a light conversion layer 73 disposed on the display layer 72, wherein the display layer 72 and the light conversion layer 73 may form a plurality of pixel units P, the plurality of pixel units P may respectively have a first side S, and the plurality of pixel units P respectively emit a plurality of display lights which emit from the first sides S; and a plurality of photoelectric conversion units PSC respectively disposed adjacent to the first sides S. More specifically, the display layer 72 comprises a first display unit 721, a second display unit 722 and a third display unit 723, the light conversion layer 73 comprises a first light conversion unit 731, a second light conversion unit 732 and a third light conversion unit 733. The first pixel unit P1 comprises a first display unit 721 and a first light conversion unit 731, the second pixel unit P2 comprises a second display unit 722 and a second light conversion unit 732, and the third pixel unit P3 comprises a third display unit 723 and a third light conversion unit 733, wherein the first light conversion unit 731 is disposed between the first display unit 721 and the first photoelectric conversion unit PSC1, the second light conversion unit 732 is disposed between the second display unit 722 and the second photoelectric conversion unit PSC2, and the third light conversion unit 733 is disposed between the third display unit 723 and the third photoelectric conversion unit PSC3.

In the present disclosure, the materials of the substrate 71 and the counter substrate 74 may comprise a rigid substrate material or a flexible substrate material; but the present disclosure is not limited thereto. In one embodiment of the present disclosure, even not shown in the figure in detail, the display layer 72 may comprise an electrode layer, an active component, a conductive line, a display medium, an insulating layer or a combination thereof; but the present disclosure is not limited thereto. In the present disclosure, the display medium may comprise a light emitting diode, and the light emitting diode may, for example, comprise a mini LED or a micro LED; but the present disclosure is not limited thereto.

In one embodiment of the present disclosure, the display layer 72 may, for example, provide or emit blue light. The light conversion unit 73 may selectively convert the blue light into light with corresponding colors, and for example, the first light conversion unit 731 may selectively convert the blue light into blue light with other wavelength range; or the first light conversion unit 731 may be, for example, replaced by other optical unit (a light scattering unit) and not convert the blue light into light with other colors. The second light conversion unit 732 may convert the blue light into green light, and the third light conversion unit 733 may convert the blue light into red light. Thus, the plurality of pixel units P (the first pixel unit P1, the second pixel unit P2 and the third pixel unit P3) mat respectively emit display lights with different colors. In addition, the first photoelectric conversion unit PSC1 may, for example, absorb visible light outside the blue light wavelength range, the second photoelectric conversion unit PSC2 may, for example, absorb the visible light outside the green light wavelength range, and the third photoelectric conversion unit PSC3 may, for example, absorb visible light outside the red light wavelength range. Thus, first photoelectric conversion unit PSC1 may, for example, allow most or at least part of the blue light to pass through, the second photoelectric conversion unit PSC2 may, for example, allow most or at least part of the green light to pass through, and the third photoelectric conversion unit PSC3 may, for example, allow most or at least part of the red light to pass through. Therefore, in the present disclosure, the above photoelectric conversion units may have the function of a filter layer, so the filter layer may be optionally omitted in the electronic device to save materials. The above photoelectric conversion units PSC may, for example, absorb display light with different wavelengths and converts the light into electrical energy, which can be stored in the energy storage device E and subsequently provided to the driving circuit D for use, thereby saving power consumption.

In one embodiment of the present disclosure, as shown in FIG. 9, the counter substrate 74 may be disposed on the photoelectric conversion units PSC (for example, the first photoelectric conversion unit PSC1, the second photoelectric conversion unit PSC2 and the third photoelectric conversion unit PSC3), wherein the photoelectric conversion units PSC (for example, the first photoelectric conversion unit PSC1, the second photoelectric conversion unit PSC2 and the third photoelectric conversion unit PSC3) may be disposed between the counter substrate 74 and the display layer 72 (or the pixel units P). The first photoelectric conversion unit PSC1 is disposed between the first pixel unit P1 and the counter substrate 74, the second photoelectric conversion unit PSC2 is disposed between the second pixel unit P2 and the counter substrate 74, and the third photoelectric conversion unit PSC3 is disposed between the third pixel unit P3 and the counter substrate 74. In other words, the photoelectric conversion units PSC (for example, the first photoelectric conversion unit PSC1, the second photoelectric conversion unit PSC2 and the third photoelectric conversion unit PSC3) may be respectively disposed inside the panel 7. Even not shown in the figure, the counter substrate 74 may also be disposed between the photoelectric conversion units PSC (for example, the first photoelectric conversion unit PSC1, the second photoelectric conversion unit PSC2 and the third photoelectric conversion unit PSC3) and the display layer 72 (or the display units). In other words, the photoelectric conversion units PSC (for example, the first photoelectric conversion unit PSC1, the second photoelectric conversion unit PSC2 and the third photoelectric conversion unit PSC3) may be respectively disposed outside the panel 7.

In one embodiment of the present disclosure, even not shown in the figure, when the display layer 72 provides or emits white light, the light conversion layer 73 (for example, the first light conversion unit 731, the second light conversion unit 732 and the third light conversion unit 733) may be omitted in the panel 7. In this case, the first sides S of the plurality of pixel units P in the display layer 72 may refer to the upper surface of the display layer 72; but the present disclosure is not limited thereto.

In the present disclosure, other components and materials in the electronic device of FIG. 9 can be as those described related to FIG. 5 and will not be described again here.

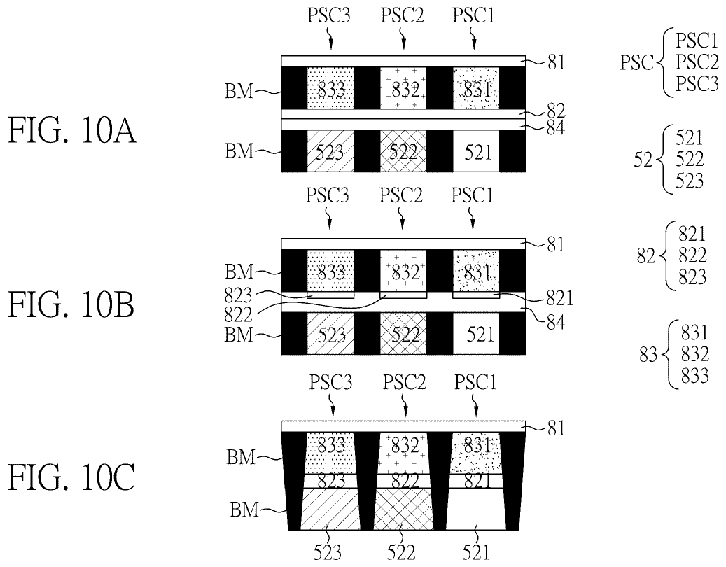

FIG. 10A is an enlarge view of a part of an electronic device according to one embodiment of the present disclosure. Herein, for convenience of explanation, FIG. 10A takes the electronic device of FIG. 5, FIG. 7 or FIG. 9 as an example and omits some components; but the present disclosure is not limited thereto.

In one embodiment of the present disclosure, as shown in FIG. 10A, the electronic device may comprise a plurality of photoelectric conversion units PSC disposed on the light conversion layer 52. The light conversion layer 52 may comprise a plurality of light conversion units, and each light conversion unit is disposed corresponding to one of the photoelectric conversion unit PSC. The plurality of light conversion units may, for example, comprise a first light conversion unit 521, a second light conversion unit 522 and a third light conversion unit 523, and the plurality of photoelectric conversion units PSC may, for example, comprise a first photoelectric conversion unit PSC1, a second photoelectric conversion unit PSC2 and a third photoelectric conversion unit PSC3, wherein the first light conversion unit 521 may be disposed corresponding to the first photoelectric conversion unit PSC1, the second light conversion unit 522 may be disposed corresponding to the second photoelectric conversion unit PSC2, and the third light conversion unit 523 may be disposed corresponding to the third photoelectric conversion unit PSC3.

In one embodiment of the present disclosure, as shown in FIG. 10A, the photoelectric conversion unit PSC may comprise: an upper electrode layer 81; a bottom electrode layer 82 disposed opposite to the upper electrode layer 81; and a perovskite light absorbing layer 83 disposed between the upper electrode layer 81 and the bottom electrode layer 82. In the present disclosure, the upper electrode layer 81 and the bottom electrode layer 82 may be respectively an entire surface electrode; but the present disclosure is not limited thereto. The perovskite light absorbing layer 83 may comprise a first perovskite light absorbing layer 831, a second perovskite light absorbing layer 832 and a third perovskite light absorbing layer 833. Thus, the first photoelectric conversion unit PSC1 comprises a part of the upper electrode layer 81, the first perovskite light absorbing layer 831 and a part of the bottom electrode layer 82, the second photoelectric conversion unit PSC2 comprises a part of the upper electrode layer 81, the second perovskite light absorbing layer 832 and a part of the bottom electrode layer 82, and the third photoelectric conversion unit PSC3 comprises a part of the upper electrode layer 81, the third perovskite light absorbing layer 833 and a part of the bottom electrode layer 82. In the present disclosure, the materials of the upper electrode layer 81 and the bottom electrode layer 82 may respectively comprise a transparent conductive layer, such as indium tin oxide (ITO), aluminum zinc oxide (AZO), indium zinc oxide (IZO), fluorine-doped tin oxide (FTO) or a combination thereof; but the present disclosure is not limited thereto.

In one embodiment of the present disclosure, as shown in FIG. 10A, a transparent insulating layer 84 is disposed between the bottom electrode layer 82 and the light conversion layer 52. In one embodiment of the present disclosure, even not shown in the figure, the transparent insulating layer 84 may be selectively removed. In the present disclosure, the material of the transparent insulating layer 84 may comprise silicon oxide, silicon oxynitride, silicon nitride, aluminum oxide, resin, polymer, photoresist, or a combination thereof; but the present disclosure is not limited thereto.

In one embodiment of the present disclosure, as shown in FIG. 10A, a black matrix layer BM (or a separation material layer) may be selectively disposed between adjacent light conversion units. For example, a black matrix layer BM (or a separation material layer) may be disposed between the first light conversion unit 521, the second light conversion unit 522 and the third light conversion unit 523 to reduce the occurrence of light mixing and improve display quality. In one embodiment of the present disclosure, as shown in FIG. 10A, a black matrix layer BM (or a separation material layer) may be disposed between adjacent perovskite light absorbing layers 83 (the first perovskite light absorbing layer 831, the second perovskite light absorbing layer 832 and the third perovskite light absorbing layer 833); but the present disclosure is not limited thereto. In the present disclosure, the materials of the black matrix layer BM and the separation material layer may be referred to the above.

In one embodiment of the present disclosure, the photoelectric conversion unit PSC and/or the light conversion layer of FIG. 5, FIG. 7 and FIG. 9 may have the structure shown in FIG. 10A, which are not described again. In addition, the plurality of photoelectric conversion units PSC of FIG. 6 and FIG. 8 may also have the structure of the photoelectric conversion unit PSC shown in FIG. 10A, which are not described again.

FIG. 10B is an enlarge view of a part of an electronic device according to one embodiment of the present disclosure, wherein FIG. 10B is similar to FIG. 10A except for the following differences.

In one embodiment of the present disclosure, as shown in FIG. 10B, the upper electrode layer 81 and/or the bottom electrode layer 82 of the photoelectric conversion unit PSC may selectively be a patterned electrode. For example, the bottom electrode layer 82 may comprise a first bottom electrode 821, a second bottom electrode 822 and a third bottom electrode 823, wherein the first bottom electrode 821 is disposed corresponding to the first perovskite light absorbing layer 831, the second bottom electrode 822 is disposed corresponding to the second perovskite light absorbing layer 832, and the third bottom electrode 823 is disposed corresponding to the third perovskite light absorbing layer 833. In one embodiment of the present disclosure, even not shown in the figure, the upper electrode layer 81 may be selectively a patterned electrode.

In one embodiment of the present disclosure, as shown in FIG. 10B, a transparent insulating layer 84 may be disposed between the perovskite light absorbing layer 83 and the light conversion layer 52. In one embodiment of the present disclosure, even not shown in the figure, the transparent insulating layer 84 may be selectively removed. In the present disclosure, the material of the transparent insulating layer 84 may comprise silicon oxide, silicon oxynitride, silicon nitride, aluminum oxide, resin, polymer, photoresist, or a combination thereof; but the present disclosure is not limited thereto.

In one embodiment of the present disclosure, the photoelectric conversion unit PSC and the light conversion layer shown in FIG. 5, FIG. 7 and FIG. 9 may have the structure shown in FIG. 10B, which are not described again. In addition, the plurality of photoelectric conversion units PSC shown in FIG. 6 and FIG. 8 may also have the structure of the photoelectric conversion unit PSC shown in FIG. 10B, which are not described again.

FIG. 10C is an enlarge view of a part of an electronic device according to one embodiment of the present disclosure, wherein FIG. 10C is similar to FIG. 10A except for the following differences.

In one embodiment of the present disclosure, as shown in FIG. 10C, the upper electrode layer 81 and/or the bottom electrode layer 82 of the photoelectric conversion unit PSC may be selectively a patterned electrode. For example, the bottom electrode layer 82 may comprise a first bottom electrode 821, a second bottom electrode 822 and a third bottom electrode 823, wherein the first bottom electrode 821 is disposed corresponding to the first perovskite light absorbing layer 831, the second bottom electrode 822 is disposed corresponding to the second perovskite light absorbing layer 832, and the third bottom electrode 823 is disposed corresponding to the third perovskite light absorbing layer 833. In one embodiment of the present disclosure, even not shown in the figure, the upper electrode layer 81 may be selectively a patterned electrode.

In one embodiment of the present disclosure, as shown in FIG. 10C, in the top view Z, the area of the light conversion unit and the area of the perovskite light absorbing layer 83 corresponding thereto may be different. For example, the area of the first light conversion unit 521 is different from the area of the first perovskite light absorbing layer 831, the area of the second light conversion unit 522 may be different from the area of the second perovskite light absorbing layer 832, and the area of the third light conversion unit 523 may be different from the area of the third perovskite light absorbing layer 833. The “the area of a certain component is different from the area of another component” means that in the top view Z of the electronic device, the projected area of the certain component is different from the projected area of another component.

In one embodiment of the present disclosure, as shown in FIG. 10C, a transparent insulating layer 84 (as shown in FIG. 10A) may selectively not be disposed between the bottom electrode layer 82 and the light conversion layer 52. In other words, the bottom electrode layer 82 may contact the light conversion layer 52; but the present disclosure is not limited thereto. It should be noted that, the photoelectric conversion unit shown in FIG. 10A to FIG. 10C omits the electron transportation layer and the hole transportation layer shown in FIG. 3A or FIG; and actual photoelectric conversion units include, for example, the electron transportation layer and the hole transportation layer shown in FIG. 3A or FIG. 3B.

In one embodiment of the present disclosure, the photoelectric conversion unit PSC and the light conversion layer shown in FIG. 5, FIG. 7 and FIG. 9 may have the structure shown in FIG. 10C, which are not described again. In addition, the plurality of photoelectric conversion units PSC shown in FIG. 6 or FIG. 8 may also have the structure of the photoelectric conversion unit PSC shown in FIG. 10C, which are not described again.

The above specific examples are to be construed as illustrative only and not in any way limiting of the remainder of the disclosure.

Although the present disclosure has been explained in relation to its embodiment, it is to be understood that many other possible modifications and variations can be made without departing from the spirit and scope of the disclosure as hereinafter claimed.

1. An electronic device, comprising:
a first panel, comprising:
a first display layer having a first side and a second side opposite to each other, wherein the first display layer receives an incident light and reflects a first reflected light, light in the incident light other than the first reflected light is a first transmitting light, the first side is a light emitting side for the first reflected light, and the second side is a transmitting side for the first transmitting light;
a first photoelectric conversion unit disposed adjacent to the second side, wherein the first photoelectric conversion unit absorbs at least part of the first transmitting light and converts it into electrical energy; and
a second panel disposed opposite to the first panel, wherein the second panel comprises a second display layer, and the first photoelectric conversion unit is disposed between the first display layer and the second display layer.

2. The electronic device of claim 1, wherein the second display layer receives the first transmitting light that is not absorbed by the first photoelectric conversion unit and reflects a second reflected light, and a wavelength of the first reflected light is different from a wavelength of the second reflected light.

3. The electronic device of claim 1, wherein the first photoelectric conversion unit comprises a perovskite solar cell, a dye-sensitized solar cell or a combination thereof.

4. The electronic device of claim 1, further comprising a second photoelectric conversion unit disposed adjacent to the second panel, wherein light absorbed by the first photoelectric conversion unit is different from light absorbed by the second photoelectric conversion unit.

5. The electronic device of claim 4, wherein the second photoelectric conversion unit comprises a perovskite solar cell, a dye-sensitized solar cell or a combination thereof.

6. The electronic device of claim 4, further comprising a third panel, wherein the second panel is disposed between the first panel and the third panel, and the second photoelectric conversion unit is disposed between the second panel and the third panel.

7. The electronic device of claim 6, further comprising a third photoelectric conversion unit disposed adjacent to the third panel, wherein light absorbed by the third photoelectric conversion unit is different from light absorbed by the second photoelectric conversion unit and the light absorbed by the first photoelectric conversion unit.

8. The electronic device of claim 7, wherein the third photoelectric conversion unit comprises a perovskite solar cell, a dye-sensitized solar cell or a combination thereof.

9. The electronic device of claim 1, wherein the first panel comprises:
a first substrate;
a second substrate disposed opposite to the first substrate, wherein the first display layer is disposed between the first substrate and the second substrate; and
a first electrode layer disposed between the first substrate and the first display layer,
wherein the first photoelectric conversion unit is disposed between the first substrate and the first electrode layer.

10. The electronic device of claim 1, wherein the first panel comprises a first substrate and a second substrate opposite to each other, the second panel comprises a third substrate and a fourth substrate opposite to each other, the fourth substrate is adjacent to the first substrate, and the first photoelectric conversion unit is disposed between the first substrate and the fourth substrate.

11. The electronic device of claim 1, wherein the first panel comprises a plurality of pixel regions, and the first photoelectric conversion unit and the plurality of pixel regions are overlapped in a top view of the electronic device.

12. The electronic device of claim 1, further comprising another photoelectric conversion unit, wherein the first display layer is disposed between the first photoelectric conversion unit and the another photoelectric conversion unit, and the another photoelectric conversion unit is used to absorb ultraviolet light or infrared light and convert it into electrical energy.

13. An electronic device, comprising:
a panel, comprising:
a first pixel unit and a second pixel unit respectively having a first side, wherein the first pixel unit and the second pixel unit respectively emit different display lights and emit from the first sides of the first pixel unit and the second pixel unit respectively;
a first photoelectric conversion unit adjacent to the first side of the first pixel unit; and
a second photoelectric conversion unit adjacent to the first side of the second pixel unit, wherein the first photoelectric conversion unit absorbs at least part of the display light emitted from the first pixel unit and converts it into electrical energy, and the second photoelectric conversion unit absorbs at least part of the display light emitted from the second pixel unit and converts it into electrical energy,
wherein a wavelength range of light absorbed by the first photoelectric conversion unit is different from a wavelength range of light absorbs by the second photoelectric conversion unit.

14. The electronic device of claim 13, wherein the first photoelectric conversion unit and the second photoelectric conversion unit respectively comprises a perovskite solar cell, a dye-sensitized solar cell or a combination thereof.

15. The electronic device of claim 13, further comprising a third photoelectric conversion unit, wherein the panel further comprise a third pixel unit, and the third photoelectric conversion unit is disposed adjacent to a first side of the third pixel unit.

16. The electronic device of claim 15, wherein a wavelength range of light absorbed by the third photoelectric conversion unit is different from the wavelength range of light absorbed by the first photoelectric conversion unit and the wavelength range of light absorbed by the second photoelectric conversion unit.

17. The electronic device of claim 13, wherein the panel further comprises a substrate and a counter substrate opposite to each other, the first pixel unit and the second pixel unit are disposed between the substrate and the counter substrate, the first photoelectric conversion unit is disposed between the first pixel unit and the counter substrate, and the second photoelectric conversion unit is disposed between the second pixel unit and the counter substrate.

18. The electronic device of claim 13, wherein the first pixel unit comprises a display layer and a light conversion layer, and the light conversion layer is disposed between the display layer and the first photoelectric conversion unit.

19. The electronic device of claim 13, further comprising another photoelectric conversion unit disposed on the panel and overlapped with the first pixel unit and the second pixel unit, wherein a wavelength range of light absorbed by the another photoelectric conversion unit is different from the wavelength range of light absorbed by the first photoelectric conversion unit and the wavelength range of light absorbed by the second photoelectric conversion unit.

20. The electronic device of claim 13, further comprising a black matrix layer disposed between the first photoelectric conversion unit and the second photoelectric conversion unit.
